(19) United States
(12) Patent Application Publication
(10) Pub. No.: US 2021/0202547 A1
(43) Pub. Date: Jul. 1, 2021

(54) IMAGE SENSOR AND METHOD OF FABRICATING THE SAME

(71) Applicant: SAMSUNG ELECTRONICS CO., LTD., Suwon-si (KR)

(72) Inventors: Yongjin CHO, Suwon-si (KR); Eun-A KWAK, Hwaseong-si (KR); Mi-Jin KWON, Anyang-si (KR); Young-Mi LEE, Suwon-si (KR)

(73) Assignee: SAMSUNG ELECTRONICS CO., LTD., Suwon-si (KR)

(21) Appl. No.: 16/922,594

(22) Filed: Jul. 7, 2020

(30) Foreign Application Priority Data
Dec. 26, 2019 (KR) 10-2019-0175615

(51) Int. Cl. H01L 27/146

(52) U.S. Cl. CPC H01L 27/1463; H01L 27/14603

(57) ABSTRACT

An image sensor includes a first pixel row and a second pixel row, each of the first and second pixel rows including pixels arranged in a first direction, the first and second pixel rows being adjacent to each other in a second direction crossing the first direction. The image sensor further includes device isolation patterns disposed between the first and second pixel rows and spaced apart from each other in the first direction, and supporting patterns disposed between the first and second pixel rows and interposed between the device isolation patterns. Each of the supporting patterns is connected to corresponding ones of the pixels.

### CROSS-REFERENCE TO RELATED APPLICATION

This U.S. non-provisional patent application claims priority under 35 U.S.C. § 119 to Korean Patent Application No. 10-2019-0175615, filed on Dec. 26, 2019, in the Korean Intellectual Property Office, the entire contents of which are incorporated by reference herein in their entirety.

### BACKGROUND

### 1. Field

Devices, apparatuses, and methods consistent with the present disclosure relate to an image sensor and a method of fabricating the same, and in particular, to a complementary metal oxide semiconductor (CMOS) image sensor and a method of fabricating the same.

### 2. Description of Related Art

An image sensor is a semiconductor device that converts optical images into electrical signals. With the recent development of the computer and communication industries, there is an increased demand for high-performance image sensors in a variety of applications such as digital cameras, camcorders, personal communication systems, gaming machines, security cameras, micro-cameras for medical applications, and/or robots. The image sensor may be classified into two types: a charge coupled device (CCD) type and a complementary metal-oxide-semiconductor (CMOS) type. In general, the CMOS-type image sensor is called “CIS”. The CIS includes a plurality of pixels, which are two-dimensionally arranged. Each of the pixels includes a photodiode (PD) that coverts incident light into an electrical signal. Recently, to improve the resolution of the CIS, the pixels are provided to have an increased aspect ratio.

### SUMMARY

It is an aspect to provide a method of fabricating an image sensor with a reduced process failure and an image sensor fabricated thereby.

It is another aspect to provide an image sensor with improved resolution and sensitivity characteristics and a method of fabricating the same.

According to an aspect of an embodiment, there is provided an image sensor comprising a first pixel row and a second pixel row, each of the first and second pixel rows comprising a plurality of pixels arranged in a first direction, the first and second pixel rows being adjacent to each other in a second direction crossing the first direction; a plurality of device isolation patterns disposed between the first pixel row and the second pixel row, the plurality of device isolation patterns being spaced apart from each other in the first direction; and a plurality of supporting patterns disposed between the first pixel row and the second pixel row, each of the plurality of supporting patterns interposed between an adjacent two of the plurality of device isolation patterns, wherein each of the plurality of supporting patterns is connected to corresponding ones of the plurality of pixels.

According to another aspect of an embodiment, there is provided an image sensor comprising a first pixel row and a second pixel row, each of the first and second pixel rows comprising a plurality of pixels arranged in a first direction, the first and second pixel rows being adjacent to each other in a second direction crossing the first direction; a plurality of first device isolation patterns disposed between the first pixel row and the second pixel row, the plurality of first device isolation patterns being spaced apart from each other in the first direction; and a plurality of second device isolation patterns disposed between the plurality of first device isolation patterns, wherein each of the plurality of second device isolation patterns comprises an isolation pattern disposed between corresponding ones of the plurality of first device isolation patterns; and an insulating pattern interposed between the isolation pattern and each of the corresponding ones of the plurality of first device isolation patterns.

According to yet another aspect of an embodiment, there is provided a method comprising forming a plurality of trenches in a substrate to define a plurality of pixel regions and a plurality of supporting patterns between the plurality of pixel regions; doping side surfaces of the plurality of pixel regions and the plurality of supporting patterns, which are exposed by the plurality of trenches, with impurities; and forming a plurality of first device isolation patterns to fill the plurality of trenches, wherein each of the plurality of supporting patterns is connected to corresponding ones of the plurality of pixel regions.

According to yet another aspect of an embodiment, there is provided a method comprising forming a plurality of first trenches, which are extended in a first direction and are spaced apart from each other in a second direction crossing the first direction, in a substrate; forming a plurality of preliminary device isolation patterns to fill the plurality of first trenches; forming a plurality of second trenches in the substrate to cross the plurality of first trenches; and forming a plurality of second device isolation patterns to fill the plurality of second trenches, wherein each of the plurality of preliminary device isolation patterns is divided into a plurality of first device isolation patterns by the plurality of second trenches.

### BRIEF DESCRIPTION OF THE DRAWINGS

Example embodiments will be more clearly understood from the following brief description taken in conjunction with the accompanying drawings, in which:

FIG. 1 is a circuit diagram illustrating a pixel of an image sensor according to an embodiment;

FIG. 2 is a plan view illustrating an image sensor according to an embodiment;

FIG. 3 is an enlarged view illustrating a portion P1 of the image sensor of FIG. 2, according to an embodiment;

FIGS. 4A and 4B are sectional views respectively taken along lines A-A′ and B-B′, respectively, of FIG. 2;

FIG. 5 is a plan view illustrating a method of fabricating an image sensor according to an embodiment;

FIGS. 6A and 6B are sectional views respectively taken along lines A-A′ and B-B′, respectively, of FIG. 5;

FIGS. 7A, 7B, 8A, and 8B are sectional views, with FIGS. 7A and 8A being taken along lines A-A′ and FIGS. 7B and 8B being taken along lines B-B′ of FIG. 2, to illustrate a method of fabricating an image sensor according to an embodiment;

FIG. 9 is a plan view illustrating an image sensor according to an embodiment;

FIG. 10 is a sectional view taken along a line B-B′ of FIG. 9;

FIG. 11 is a plan view illustrating a method of fabricating an image sensor according to an embodiment;

FIGS. 12A and 12B are sectional views respectively taken along lines A-A′ and B-B′, respectively, of FIG. 11;

FIGS. 13A and 13B are sectional views, which are respectively taken along lines A-A′ and B-B′ of FIG. 9, to illustrate a method of fabricating an image sensor according to an embodiment;

FIG. 14 is a plan view illustrating an image sensor according to an embodiment;

FIG. 15 is a sectional view taken along a line B-B′ of FIG. 14;

FIGS. 16 and 18 are plan views illustrating a method of fabricating an image sensor according to an embodiment;

FIGS. 17A and 17B are sectional views respectively taken along lines A-A′ and B-B′ of FIG. 16, and FIGS. 19A and 19B are sectional views respectively taken along lines A-A′ and B-B′ of FIG. 18;

FIGS. 20A and 20B are sectional views, which are respectively taken along lines A-A′ and B-B′ of FIG. 14, to illustrate a method of fabricating an image sensor according to an embodiment;

FIG. 21 is a plan view illustrating an image sensor according to an embodiment;

FIG. 22 is an enlarged view illustrating a portion P2 of the image sensor of FIG. 21;

FIG. 23 is a sectional view taken along a line B-B′ of FIG. 21;

FIGS. 24, 26, and 28 are plan views illustrating a method of fabricating an image sensor according to an embodiment;

FIGS. 25A to 25C are sectional views respectively taken along lines A-A′, B-B′, and C-C′ of FIG. 24, FIGS. 27A to 27C are sectional views respectively taken along lines A-A′, B-B′, and C-C′ of FIG. 26, and FIGS. 29A to 29C are sectional views respectively taken along lines A-A′, B-B′, and C-C′ of FIG. 28;

FIGS. 30A to 30C are sectional views, which are respectively taken along lines A-A′, B-B′, and C-C′ of FIG. 21, to illustrate a method of fabricating an image sensor according to an embodiment;

FIG. 31 is a plan view illustrating an image sensor according to an embodiment;

FIG. 32 is a sectional view taken along a line B-B′ of FIG. 31;

FIG. 33 is a plan view illustrating a method of fabricating an image sensor according to an embodiment;

FIGS. 34A to 34C are sectional views respectively taken along lines A-A′, B-B′, and C-C′ of FIG. 33;

FIGS. 35A to 35C are sectional views, which are respectively taken along lines A-A′, B-B′, and C-C′ of FIG. 31, to illustrate a method of fabricating an image sensor according to an embodiment.

### DETAILED DESCRIPTION

Example embodiments will now be described more fully with reference to the accompanying drawings, in which example embodiments are shown.

It should be noted that these figures are intended to illustrate the general characteristics of methods, structure and/or materials utilized in certain example embodiments and to supplement the written description provided below. These drawings are not, however, to scale and may not precisely reflect the precise structural or performance characteristics of any given embodiment, and should not be interpreted as defining or limiting the range of values or properties encompassed by example embodiments. For example, the relative thicknesses and positioning of molecules, layers, regions and/or structural elements may be reduced or exaggerated for clarity. The use of similar or identical reference numbers in the various drawings is intended to indicate the presence of a similar or identical element or feature.

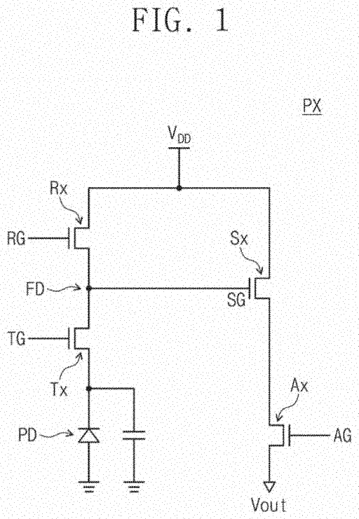

FIG. 1 is a circuit diagram illustrating a pixel of an image sensor according to an embodiment.

Referring to FIG. 1, a unit pixel PX of an image sensor may include a photoelectric conversion device PD, a transfer transistor Tx, a source follower transistor Sx, a reset transistor Rx, and a selection transistor Ax. The transfer transistor Tx, the source follower transistor Sx, the reset transistor Rx, and the selection transistor Ax may include a transfer gate TG, a source follower gate SG, a reset gate RG, and a selection gate AG, respectively.

The photoelectric conversion device PD may be a photodiode including a p-type impurity region and an n-type impurity region. A floating diffusion region FD may be provided between the transfer transistor Tx and the reset transistor Rx to serve as a drain electrode of the transfer transistor Tx. The floating diffusion region FD may also serve as a source electrode of the reset transistor Rx. The floating diffusion region FD may be electrically connected to the source follower gate SG of the source follower transistor Sx. The source follower transistor Sx may be connected to the selection transistor Ax.

Hereinafter, an operation of an image sensor according to an embodiment will be described with reference to FIG. 1. First, if an external light is incident into the photoelectric conversion device PD, electron-hole pairs may be generated in the photoelectric conversion device PD. Holes may be moved to and accumulated in the p-type impurity region of the photoelectric conversion device PD, and electrons may be moved to and accumulated in the n-type impurity region of the photoelectric conversion device PD. Electric charges may be discharged from the floating diffusion region FD by turning on the reset transistor Rx and applying a power voltage VDD to the drain electrodes of the reset transistor Rx and the source follower transistor Sx while preventing the electrons from entering the floating diffusion region FD. Thereafter, by turning on the transfer transistor Tx, the generated electric charges (e.g., electrons and holes) may be transferred to and accumulated in the floating diffusion region FD. A change in amount of the accumulated electric charges may lead to a change in gate bias of the source follower transistor Sx, and this may lead to a change in source potential of the source follower transistor Sx. Accordingly, if the selection transistor Ax is turned on, a signal associated with the electric charges may be read out through a column line.

FIG. 1 illustrates an example of the pixel, in which a single photoelectric conversion device PD and four transistors (i.e., Tx Rx, Ax, and Sx) are provided, but example embodiments are not limited to this example. For example, the image sensor may include a plurality of pixels PX, and in certain embodiments, the reset transistor Rx, the source follower transistor Sx, or the selection transistor Ax may be shared by adjacent ones of the pixels PX. In this case, an integration density of the image sensor may be increased.

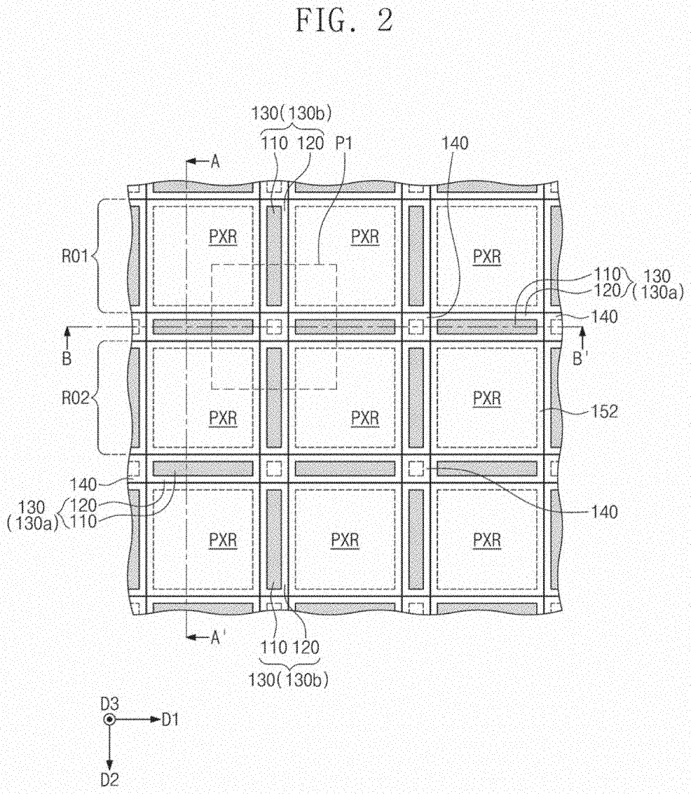

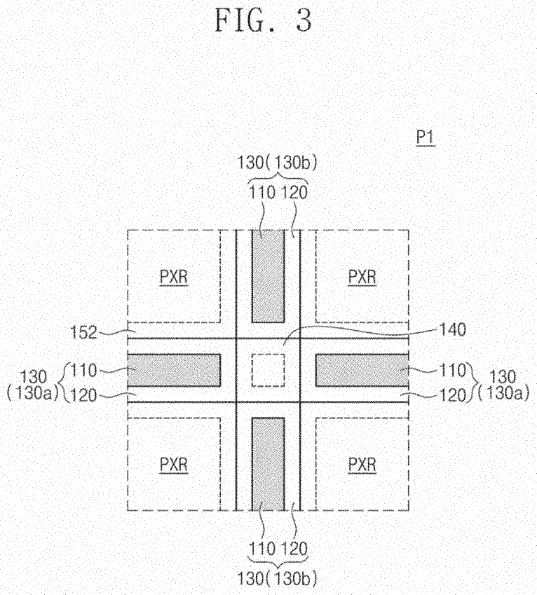

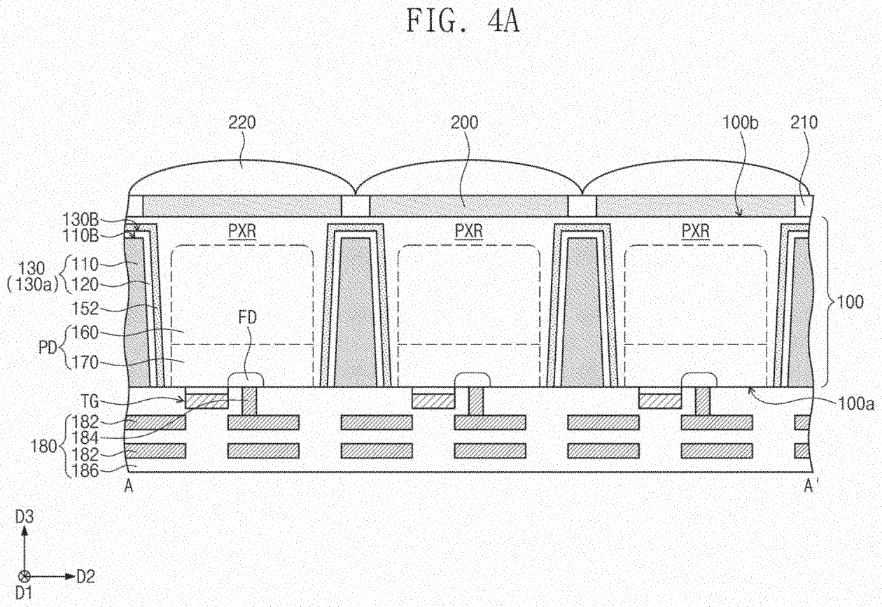

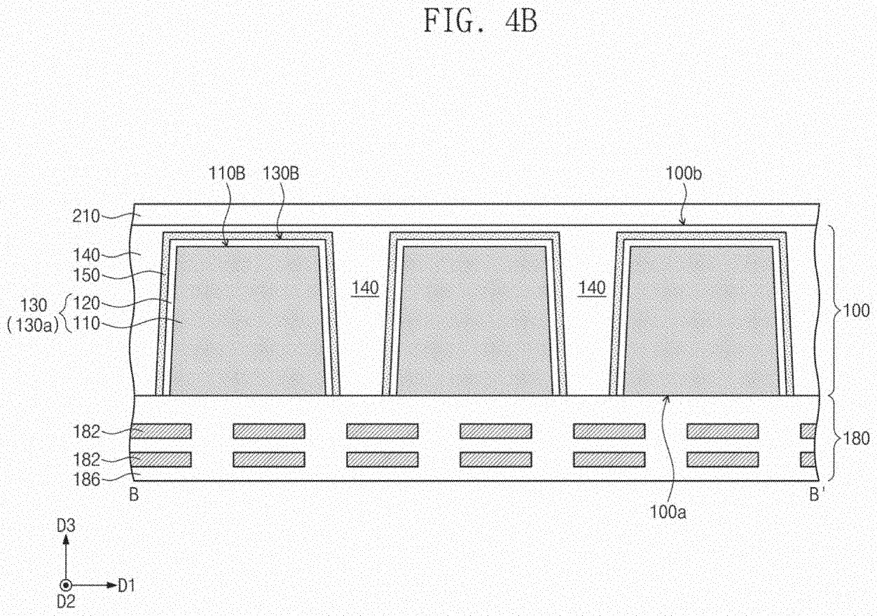

FIG. 2 is a plan view illustrating an image sensor according to an embodiment, and FIG. 3 is an enlarged view illustrating a portion P1 of the image sensor of FIG. 2. FIGS. 4A and 4B are sectional views respectively taken along lines A-A′ and B-B′, respectively, of FIG. 2.

Referring to FIGS. 2, 4A, and 4B, a substrate 100 including a plurality of pixel regions PXR may be provided. The substrate 100 may be a semiconductor substrate (e.g., a silicon wafer, a germanium wafer, a silicon-germanium wafer, a II-VI compound semiconductor wafer, or a III-V compound semiconductor wafer) or a silicon-on-insulator (SOI) wafer. The substrate 100 may have a first surface 100a and a second surface 100b that are opposite to each other.

The pixel regions PXR may be two-dimensionally arranged in a first direction D1 and a second direction D2 that are parallel to the first surface 100a of the substrate 100 (see, e.g., FIG. 2). The first direction D1 and the second direction D2 may not be parallel (for example, in some embodiments the first direction D1 and the second direction D2 may cross) to each other. Ones of the pixel regions PXR arranged in the first direction D1 may constitute a row (hereinafter, a pixel row). As an example, the substrate 100 may include a first pixel row RO1 and a second pixel row RO2, which are adjacent to each other in the second direction D2, and each of which includes a plurality of pixel regions PXR arranged in the first direction D1.

Device isolation patterns 130 may be disposed in the substrate 100 and between the pixel regions PXR. The device isolation patterns 130 may include first device isolation patterns 130a separated from each other in the first direction D1 and second device isolation patterns 130b separated from each other in the second direction D2. The first device isolation patterns 130a may be disposed between the first and second pixel rows RO1 and RO2 and may be spaced apart from each other in the first direction D1. The second device isolation patterns 130b may be disposed between the pixel regions PXR in the first pixel row RO1 and between the pixel regions PXR in the second pixel row RO2.

Each of the device isolation patterns 130 may be provided to penetrate at least a portion of the substrate 100. Each of the device isolation patterns 130 may be extended from the first surface 100a of the substrate 100 toward an internal portion of the substrate 100 in a third direction D3 perpendicular to the first surface 100a. As an example, in some embodiments, a bottom surface 130B of each of the device isolation patterns 130 may be spaced apart from the second surface 100b of the substrate 100. In other embodiments, unlike that illustrated in the drawings, the bottom surface 130B of each of the device isolation patterns 130 may be substantially coplanar with the second surface 100b of the substrate 100. Each of the device isolation patterns 130 may be disposed between adjacent ones of the pixel regions PXR to suppress or prevent a cross-talk issue between the adjacent ones of the pixel regions PXR.

Each of the device isolation patterns 130 may include an isolation pattern 110, which is provided to penetrate at least a portion of the substrate 100, and an insulating pattern 120, which is interposed between the isolation pattern 110 and the substrate 100. The isolation pattern 110 may be disposed between the adjacent ones of the pixel regions PXR, and the insulating pattern 120 may be interposed between the isolation pattern 110 and each of the adjacent ones of the pixel regions PXR. In some embodiments, a bottom surface 110B of the isolation pattern 110 may be spaced apart from the second surface 100b of the substrate 100, and the insulating pattern 120 may be extended into a region between the bottom surface 110B of the isolation pattern 110 and the second surface 100b of the substrate 100. The isolation pattern 110 may be formed of or include at least one semiconductor materials (e.g., doped poly silicon) or metallic materials (e.g., tungsten or aluminum). The insulating pattern 120 may be formed of or include at least one of, for example, silicon nitride, silicon oxide, silicon oxynitride, or high-k dielectric materials (e.g., hafnium oxide and/or aluminum oxide).

In the present specification, the isolation pattern 110 and the insulating pattern 120 of each of the first device isolation patterns 130a may be referred to as a first isolation pattern 110 and a first insulating pattern 120, respectively, and the isolation pattern 110 and the insulating pattern 120 of each of the second device isolation patterns 130b may be referred to as a second isolation pattern 110 and a second insulating pattern 120, respectively.

Supporting patterns 140 may be disposed in the substrate 100 and between the pixel regions PXR. The supporting patterns 140 may be disposed between the first and second pixel rows RO1 and RO2 and may be interposed between the first device isolation patterns 130a. The first device isolation patterns 130a and the supporting patterns 140 may be alternately and repeatedly arranged in the first direction D1, between the first and second pixel rows RO1 and RO2. Each of the supporting patterns 140 may be interposed between a corresponding pair of the second device isolation patterns 130b. The supporting patterns 140 may be protruding portions of the substrate 100 that are extended into regions between the device isolation patterns 130. Each of the supporting patterns 140 may be extended in the third direction D3 to be placed between adjacent ones of the device isolation patterns 130. The device isolation patterns 130 may be spaced apart from each other with the supporting patterns 140 interposed therebetween.

Referring to FIGS. 2 and 3, each of the supporting patterns 140 may be interposed between directly adjacent ones of the first device isolation patterns 130a and between directly adjacent ones of the second device isolation patterns 130b. Each of the supporting patterns 140 may be connected to corresponding ones of the pixel regions PXR. As an example, each of the supporting patterns 140 may be disposed between and connected to four directly adjacent ones of the pixel regions PXR. Accordingly, the supporting patterns 140 may be used to support the pixel regions PXR during a process of forming the device isolation patterns 130.

Referring back to FIGS. 2, 4A, and 4B, the isolation pattern 110 of each of the device isolation patterns 130 may be disposed between adjacent ones of the supporting patterns 140. The insulating pattern 120 of each of the device isolation patterns 130 may be extended into a region between the isolation pattern 110 and each of the adjacent ones of the supporting patterns 140.

A first doped region 150 may be disposed in each of the supporting patterns 140 and may be extended along a side surface of each of the supporting patterns 140, as best seen in FIG. 4B. In some embodiments, the first doped region 150 may be extended into a portion of the substrate 100 that is adjacent to the bottom surface 130B of each of the device isolation patterns 130. The insulating pattern 120 of each of the device isolation patterns 130 may be interposed between the isolation pattern 110 of each of the device isolation patterns 130 and the first doped region 150 and may be in contact with the first doped region 150. The isolation pattern 110 may be spaced apart from the first doped region 150 with the insulating pattern 120 interposed therebetween.

A second doped region 152 may be disposed in each of the pixel regions PXR and may be extended along a side surface of each of the pixel regions PXR. In some embodiments, the second doped region 152 may be extended into a portion of the substrate 100 that is adjacent to the bottom surface 130B of each of the device isolation patterns 130. The insulating pattern 120 of each of the device isolation patterns 130 may be interposed between the isolation pattern 110 of each of the device isolation patterns 130 and the second doped region 152 and may be in contact with the second doped region 152. The isolation pattern 110 may be spaced apart from the second doped region 152 with the insulating pattern 120 interposed therebetween. The first doped region 150 and the second doped region 152 may have the same conductivity type and may be connected to each other.

A photoelectric conversion region PD may be disposed in each of the pixel regions PXR. The photoelectric conversion region PD may be disposed in the substrate 100 and between adjacent ones of the device isolation patterns 130. The photoelectric conversion region PD may include a first impurity region 160 and a second impurity region 170. The second impurity region 170 may be disposed to be closer to the first surface 100a of the substrate 100 than the first impurity region 160. The first impurity region 160 may be a region that is doped with impurities of a first conductivity type, and the second impurity region 170 may be a region that is doped with impurities of a second conductivity type, which is different from the first conductivity type. In an embodiment, the first conductivity type and the second conductivity type may be an n-type and a p-type, respectively. In this case, the impurities of the first conductivity type may include n-type impurities, such as phosphorus, arsenic, bismuth, and/or antimony, and the impurities of the second conductivity type may include p-type impurities such as boron.

The second doped region 152 may be disposed between the photoelectric conversion region PD and each of the adjacent ones of the device isolation patterns 130. The second doped region 152 may be doped with the impurities of the second conductivity type. The second doped region 152 may prevent electrons, which are trapped in dangling bonds which may exist on the side surface of each of the pixel regions PXR, from entering the photoelectric conversion region PD, and thus the second doped region 152 may make it possible to suppress or prevent a dark current or white spot issue from occurring in the image sensor. The first doped region 150 may be doped with the impurities of the second conductivity type and may contain the same impurities as the second doped region 152.

A floating diffusion region FD may be disposed in each of the pixel regions PXR. The floating diffusion region FD may be disposed adjacent to the first surface 100a of the substrate 100 and may be spaced apart from the first impurity region 160 by the second impurity region 170. The floating diffusion region FD may be doped with impurities of the first conductivity type. A transfer gate TG may be disposed on each of the pixel regions PXR and may be disposed on the first surface 100a of the substrate 100. The transfer gate TG may be disposed adjacent to the floating diffusion region FD.

An interconnection structure 180 may be disposed on the first surface 100a of the substrate 100. The interconnection structure 180 may include an interlayered insulating layer 186, which is disposed on the first surface 100a of the substrate 100 to cover the transfer gate TG, and interconnection lines 182 and vias 184, which are disposed in the interlayered insulating layer 186. The floating diffusion region FD may be connected to a corresponding one of the vias 184, and each of the vias 184 may be connected to a corresponding one of the interconnection lines 182. The interlayered insulating layer 186 may be formed of or include at least one of silicon oxide, silicon oxynitride, or silicon nitride. The interconnection lines 182 and the vias 184 may be formed of or include at least one of conductive materials.

Color filters 200 may be disposed on the second surface 100b of the substrate 100. The color filters 200 may be disposed to be overlapped with the pixel regions PXR, respectively, when viewed in a plan view. A grid pattern 210 may be disposed on the second surface 100b of the substrate 100 and between the color filters 200. As an example, the grid pattern 210 may be disposed on the device isolation patterns 130 and the supporting patterns 140. In an embodiment, the grid pattern 210 may be formed of or include at least one of metallic materials. Micro lenses 220 may be disposed on the color filters 200. The micro lenses 220 may be disposed to be overlapped with the pixel regions PXR, respectively, when viewed in a plan view. The micro lenses 220 may change a propagation path of an external light such that the external light is incident into the pixel regions PXR.

According to an embodiment, each of the supporting patterns 140 may be disposed between adjacent ones of the pixel regions PXR and between adjacent ones of the device isolation patterns 130. Each of the supporting patterns 140 may be connected to the adjacent ones of the pixel regions PXR. Accordingly, the supporting patterns 140 may support the pixel regions PXR during a process of forming the device isolation patterns 130.

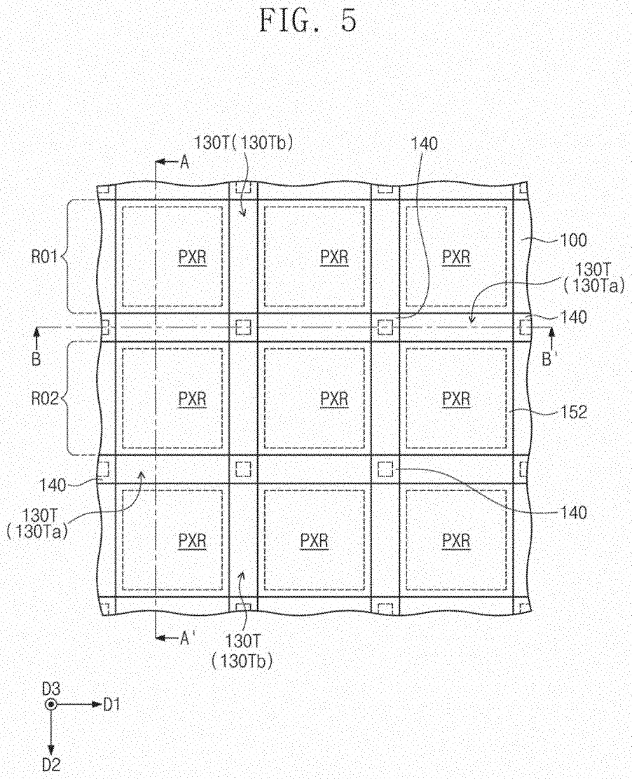

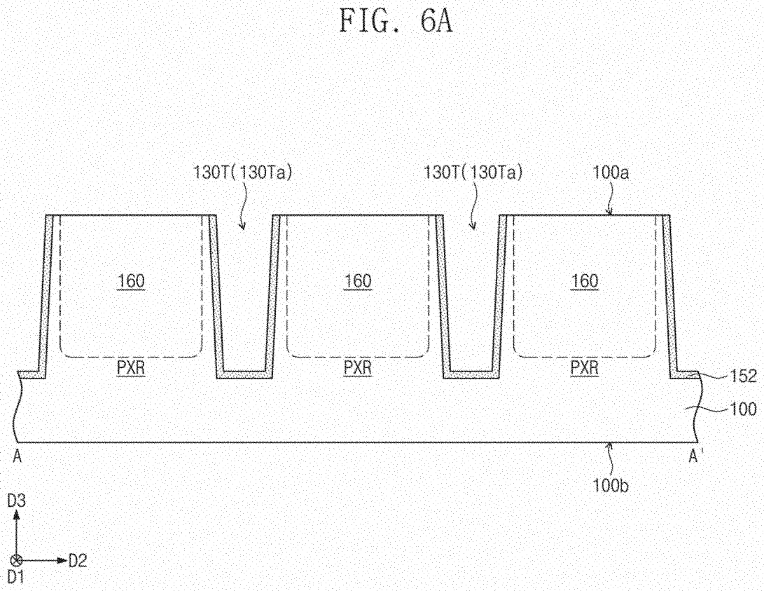

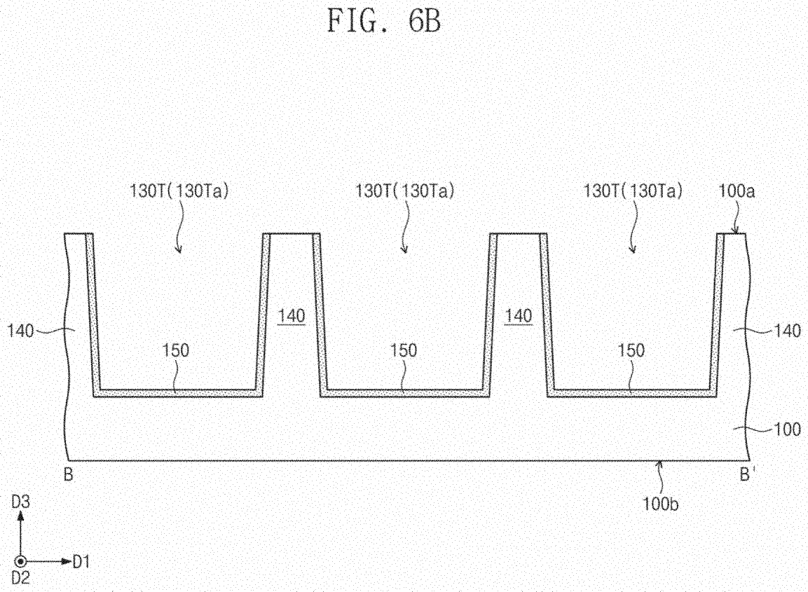

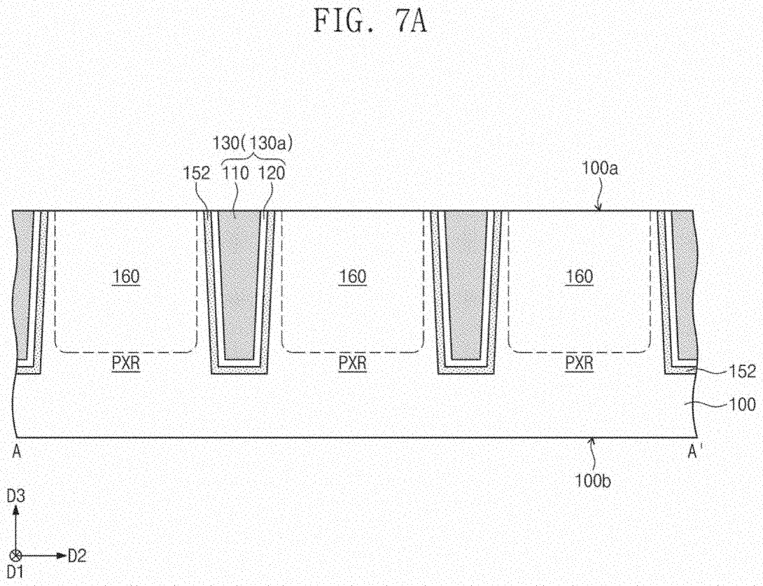

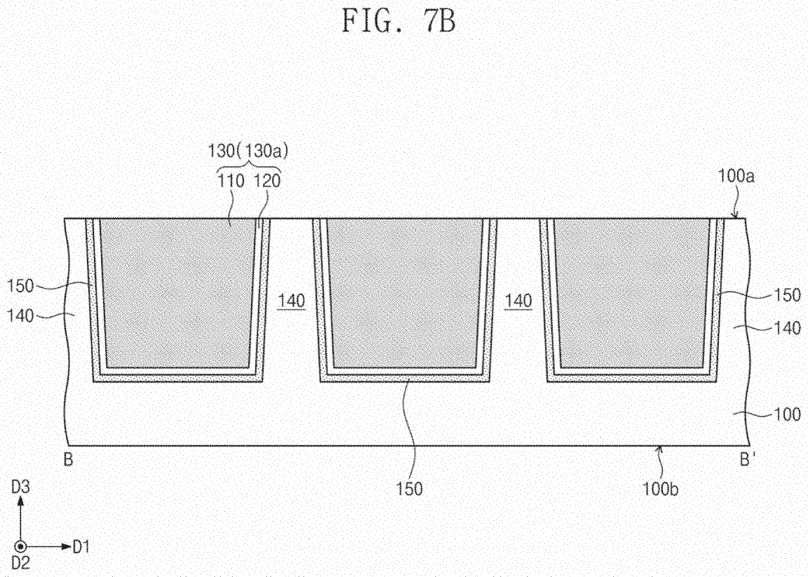

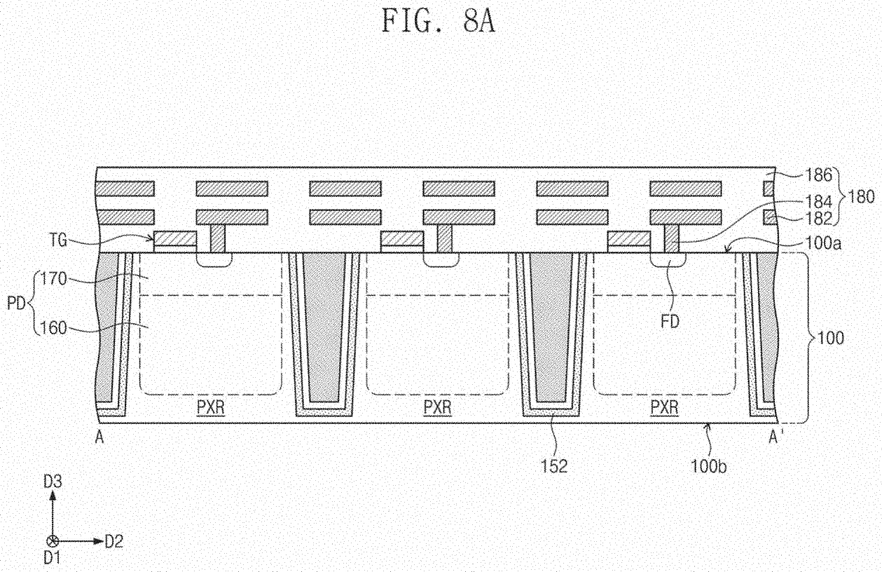

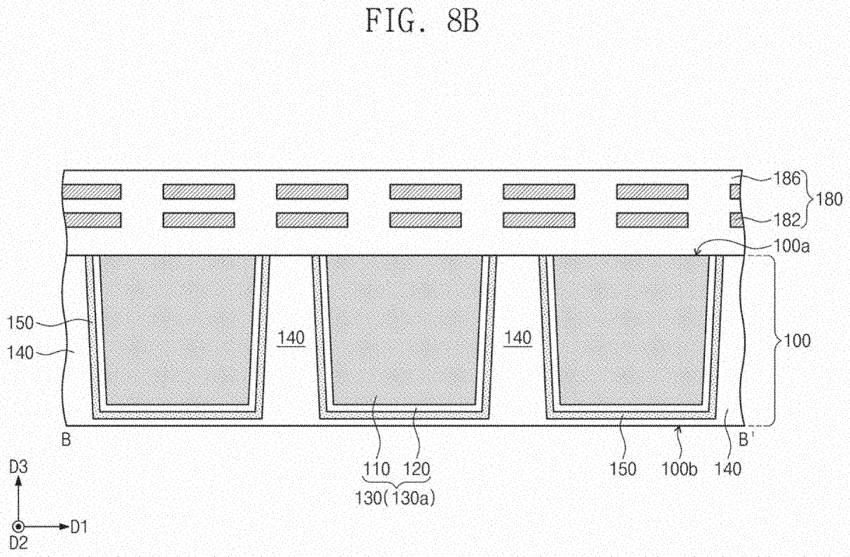

FIG. 5 is a plan view illustrating a method of fabricating an image sensor according to an embodiment, and FIGS. 6A and 6B are sectional views respectively taken along lines A-A′ and B-B′, respectively, of FIG. 5. FIGS. 7A, 7B, 8A, and 8B are sectional views, with FIGS. 7A and 8A being taken along lines A-A′ and FIGS. 7B and 8B being taken along lines B-B′ of FIG. 2, to illustrate a method of fabricating an image sensor according to an embodiment. For the sake of brevity, an element previously described with reference to FIGS. 2, 3, 4A, and 4B may be identified by the same reference number without repeating an overlapping description thereof.

Referring to FIGS. 5, 6A, and 6B, a plurality of trenches 130T may be formed in a substrate 100 to define a plurality of pixel regions PXR and a plurality of supporting patterns 140. The formation of the trenches 130T may include forming a mask pattern (not shown) on the first surface 100a of the substrate 100 and etching the substrate 100 using the mask pattern as an etch mask. The mask pattern may have openings, which define positions and shapes of the trenches 130T. The substrate 100 may include the pixel regions PXR and the supporting patterns 140 defined by the trenches 130T.

The pixel regions PXR may be two-dimensionally arranged in the first direction D1 and the second direction D2 that are parallel to the first surface 100a of the substrate 100 (see FIG. 5). As an example, the substrate 100 may include a first pixel row RO1 and a second pixel row RO2, which are adjacent to each other in the second direction D2, and each of which includes a plurality of pixel regions PXR arranged in the first direction D1. The trenches 130T may include first trenches 130Ta, which are spaced apart from each other in the first direction D1, and second trenches 130Tb, which are spaced apart from each other in the second direction D2. The first trenches 130Ta may be spaced apart from each other in the first direction D1, between the first and second pixel rows RO1 and RO2. The second trenches 130Tb may be formed between the pixel regions PXR in the first pixel row RO1 and between the pixel regions PXR in the second pixel row RO2.

The supporting patterns 140 may be formed between the pixel regions PXR. The supporting patterns 140 may be formed between the first and second pixel rows RO1 and RO2 to be spaced apart from each other in the first direction D1. Each of the supporting patterns 140 may be interposed between adjacent ones of the first trenches 130Ta and between adjacent ones of the second trenches 130Tb. Each of the supporting patterns 140 may be connected to corresponding ones of the pixel regions PXR. As an example, each of the supporting patterns 140 may be disposed between and connected to four directly adjacent ones of the pixel regions PXR.

A first impurity region 160 may be formed in each of the pixel regions PXR. The formation of the first impurity region 160 may include injecting impurities of a first conductivity type (e.g., n-type impurities) into each of the pixel regions PXR.

A first doped region 150 may be formed on side surfaces of the supporting patterns 140 exposed by the trenches 130T and in a portion of the substrate 100 adjacent to bottom surfaces of the trenches 130T. A second doped region 152 may be formed on side surfaces of the pixel regions PXR exposed by the trenches 130T and in a portion of the substrate 100 adjacent to the bottom surfaces of the trenches 130T. The formation of the first doped region 150 and the second doped region 152 may include injecting impurities of a second conductivity type (e.g., p-type impurities) into the side surfaces of the supporting patterns 140, the side surfaces of the pixel regions PXR, and the substrate 100 that are exposed by the trenches 130T. In an embodiment, the first doped region 150 and the second doped region 152 may be simultaneously formed by a plasma doping process.

Referring to FIGS. 2, 7A, and 7B, device isolation patterns 130 may be formed to fill the trenches 130T, respectively. The formation of the device isolation patterns 130 may include forming an insulating layer on the first surface 100a of the substrate 100 to partially fill each of the trenches 130T, forming an isolation layer on the insulating layer to fill a remaining portion of each of the trenches 130T, and planarizing the isolation layer and the insulating layer to expose the first surface 100a of the substrate 100. As a result of the planarization process, an insulating pattern 120 and an isolation pattern 110 may be locally formed in each of the trenches 130T. Each of the device isolation patterns 130 may include the isolation pattern 110, which is disposed in each of the trenches 130T, and the insulating pattern 120, which is interposed between an inner surface of each of the trenches 130T and the isolation pattern 110. The device isolation patterns 130 may include first device isolation patterns 130a filling the first trenches 130Ta and second device isolation patterns 130b filling the second trenches 130Tb.

Referring to FIGS. 2, 8A, and 8B, a second impurity region 170 may be formed in each of the pixel regions PXR. The formation of the second impurity region 170 may include injecting impurities of the second conductivity type (e.g., p-type impurities) into each of the pixel regions PXR. The second impurity region 170 may be formed to be closer to the first surface 100a of the substrate 100 than the first impurity region 160. A transfer gate TG may be formed on the first surface 100a of the substrate 100, and a floating diffusion region FD may be formed in a portion of the substrate 100 located at a side of the transfer gate TG. The formation of the floating diffusion region FD may include impurities of the first conductivity type (e.g., n-type impurities) into the substrate 100.

An interconnection structure 180 may be formed on the first surface 100a of the substrate 100. The formation of the interconnection structure 180 may include forming an interlayered insulating layer 186 to cover the transfer gate TG and forming interconnection lines 182 and vias 184 in the interlayered insulating layer 186. The floating diffusion region FD may be connected to a corresponding one of the vias 184, and each of the vias 184 may be connected to a corresponding one of the interconnection lines 182. Next, a chemical mechanical polishing (CMP) or grinding process may be performed on the second surface 100b of the substrate 100 to thin the substrate 100.

Referring back to FIGS. 2, 4A, and 4B, color filters 200 may be formed on the second surface 100b of the substrate 100, and in an embodiment, the color filters 200 may be overlapped with the pixel regions PXR, respectively, when viewed in a plan view. A grid pattern 210 may be formed on the second surface 10b of the substrate 100 and between the color filters 200, and in an embodiment, the grid pattern 210 may be overlapped with the device isolation patterns 130 and the supporting patterns 140, when viewed in a plan view. Micro lenses 220 may be formed on the second surface 100b of the substrate 100, and in an embodiment, the micro lenses 220 may be overlapped with the pixel regions PXR, respectively, when viewed in a plan view.

As the demand for the image sensor with improved resolution and sensitivity increases, an aspect ratio of each of the pixel regions PXR is being increased, and thus, an aspect ratio of each of the trenches 130T defining the pixel regions PXR is also being increased. However, in this case, a leaning issue of the pixel regions PXR may occur during an etching process to form the trenches 130T or during a subsequent cleaning process.

According to an embodiment, each of the supporting patterns 140 may be formed between and connected to adjacent ones of the pixel regions PXR. In this case, the supporting patterns 140 may support the pixel regions PXR, during an etching process to form the trenches 130T or during a subsequent cleaning process. Accordingly, the leaning issue of the pixel regions PXR may be prevented. Accordingly, it may be possible to reduce a process failure in a process of fabricating the image sensor. In addition, since the pixel regions PXR are supported by the supporting patterns 140, it may be easy to increase the aspect ratio of the pixel regions PXR. The increased aspect ratio of the pixel regions PXR may facilitate the improvement of resolution and sensitivity characteristics of the image sensor.

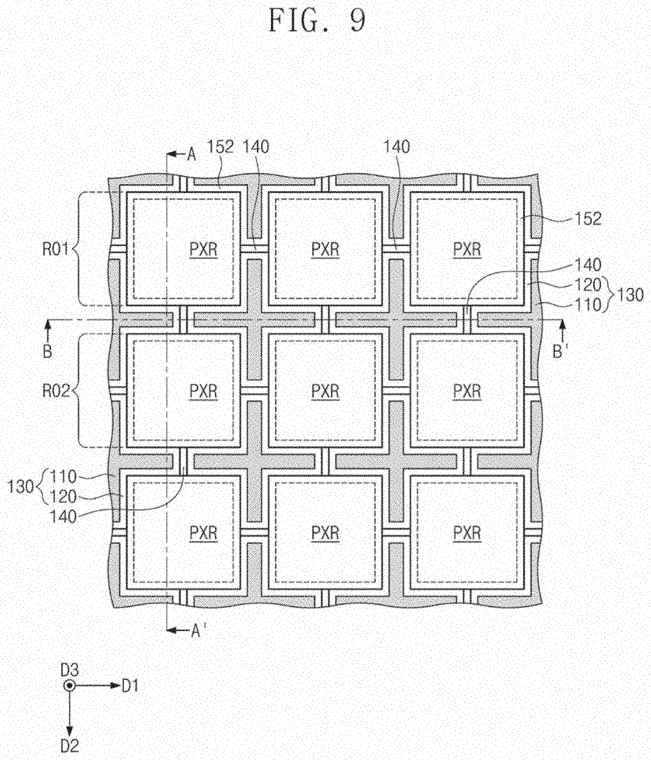

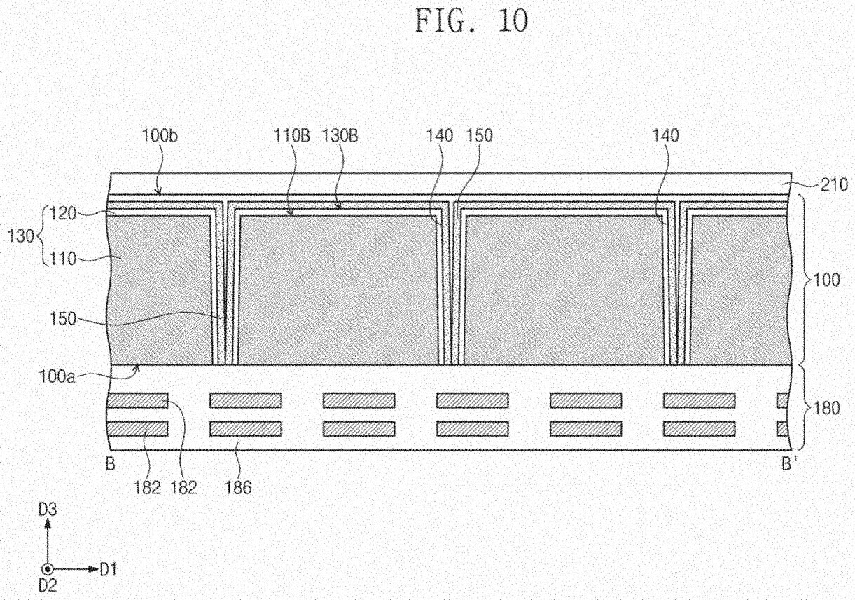

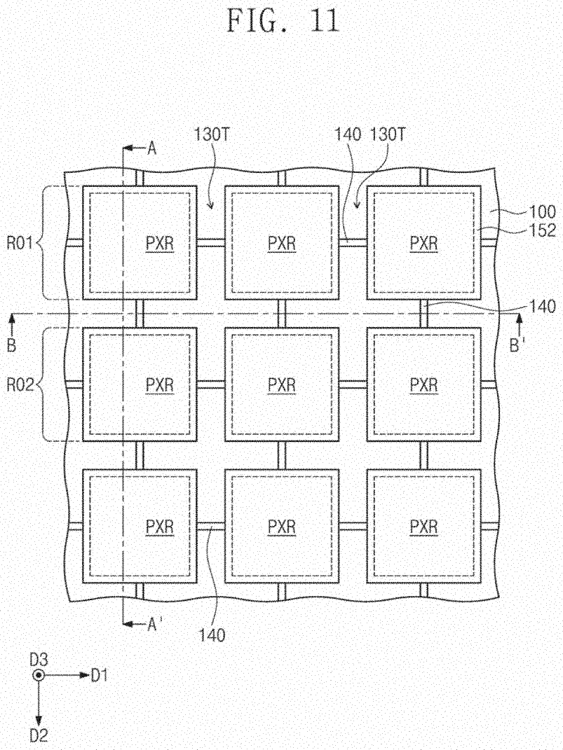

FIG. 9 is a plan view illustrating an image sensor according to an embodiment, and FIG. 10 is a sectional view taken along a line B-B′ of FIG. 9. The sectional view taken along a line A-A′ of FIG. 9 may be substantially the same as that of FIG. 4A, and thus a repeated description thereof is omitted for conciseness. For the sake of brevity, repeated description of features which are the same as those of FIGS. 2, 3, 4A, and 4B will be omitted for conciseness and features, which are different from those of the image sensor of FIGS. 2, 3, 4A, and 4B, will be mainly described below.

Referring to FIGS. 9 and 10 in conjunction with FIG. 4A, device isolation patterns 130 may be disposed in the substrate 100 and between the pixel regions PXR. As an example, the device isolation patterns 130 may be provided between the first and second pixel rows RO1 and RLO2, which are adjacent to each other in the second direction D2. The device isolation patterns 130 may be spaced apart from each other in the first direction D1, between the first and second pixel rows RO1 and RO2. Each of the device isolation patterns 130 may be extended into regions between adjacent ones of the pixel regions PXR in the first pixel row RO1 and between adjacent ones of the pixel regions PXR in the second pixel row RO2. Each of the device isolation patterns 130 may be a cross-shaped pattern, when viewed in a plan view, as best seen in FIG. 9. Each of the device isolation patterns 130 may be disposed between adjacent ones of the pixel regions PXR (e.g., between adjacent four of the pixel regions PXR).

Each of the device isolation patterns 130 may include an isolation pattern 110, which is provided to penetrate at least a portion of the substrate 100, and an insulating pattern 120, which is interposed between the isolation pattern 110 and the substrate 100. As an example, the isolation patterns 110 may be spaced apart from each other in the first direction D1, between the first and second pixel rows RO1 and RO2. The isolation pattern 110 may be extended into regions between adjacent ones of the pixel regions PXR in the first pixel row RO1 and between adjacent ones of the pixel regions PXR in the second pixel row RO2 and may be a cross-shaped pattern, when viewed in a plan view. The isolation pattern 110 may be disposed between adjacent ones of the pixel regions PXR (e.g., between each adjacent four of the pixel regions PXR). The insulating pattern 120 may be interposed between the isolation pattern 110 and each of the adjacent ones of the pixel regions PXR.

Supporting patterns 140 may be disposed in the substrate 100 and between the pixel regions PXR and may be interposed between the device isolation patterns 130. As an example, the supporting patterns 140 may be interposed between the device isolation patterns 130, between the first and second pixel rows RO1 and RO2. The device isolation patterns 130 and the supporting patterns 140 may be alternately and repeatedly arranged in the first direction D1, between the first and second pixel rows RO1 and RO2. Each of the supporting patterns 140 may be interposed between a corresponding one of the pixel regions PXR in the first pixel row RO1 and a corresponding one of the pixel region PXR in the second pixel row RO2 and may be connected to the corresponding pixel regions PXR. The supporting patterns 140 may be interposed between adjacent ones of the pixel regions PXR in the first pixel row RO1 and between adjacent ones of the pixel regions PXR in the second pixel row RO2 and may be connected to the adjacent ones of the pixel regions PXR. Accordingly, the supporting patterns 140 may be used to support the pixel regions PXR during a process of forming the device isolation patterns 130.

The isolation pattern 110 of each of the device isolation patterns 130 may be disposed between adjacent ones of the supporting patterns 140. The insulating pattern 120 of each of the device isolation patterns 130 may be extended into a region between the isolation pattern 110 and each of the adjacent ones of the supporting patterns 140.

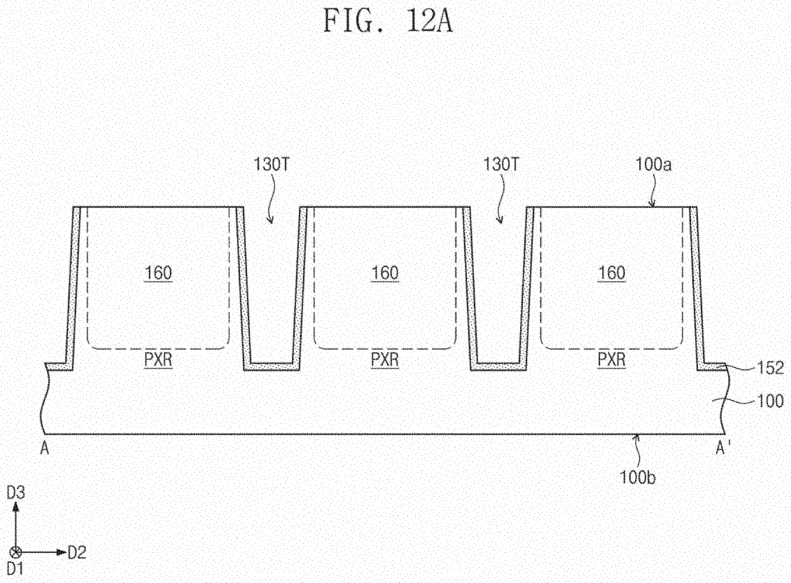

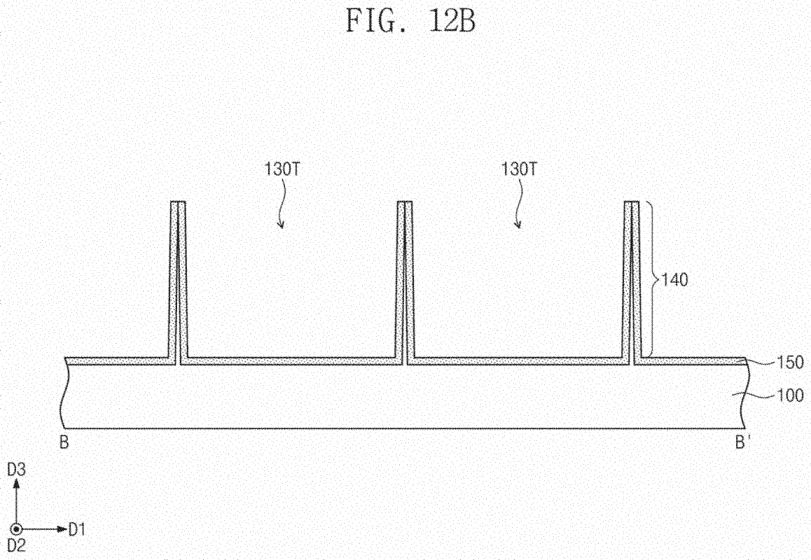

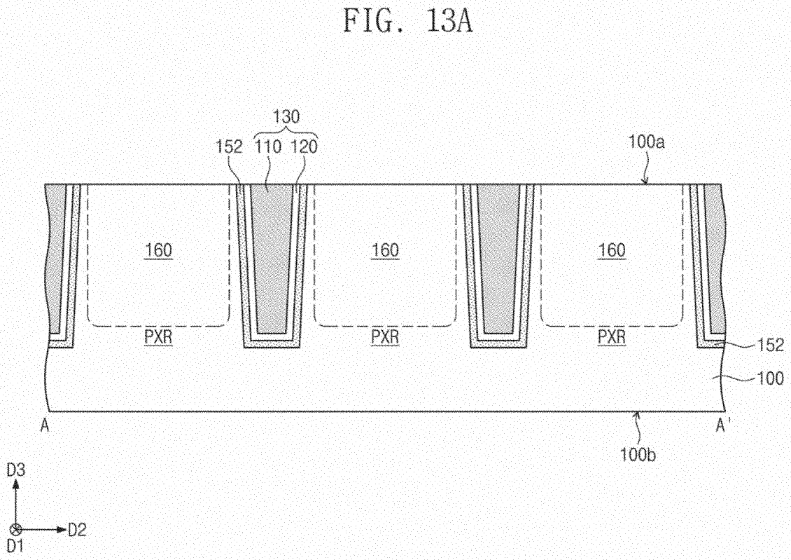

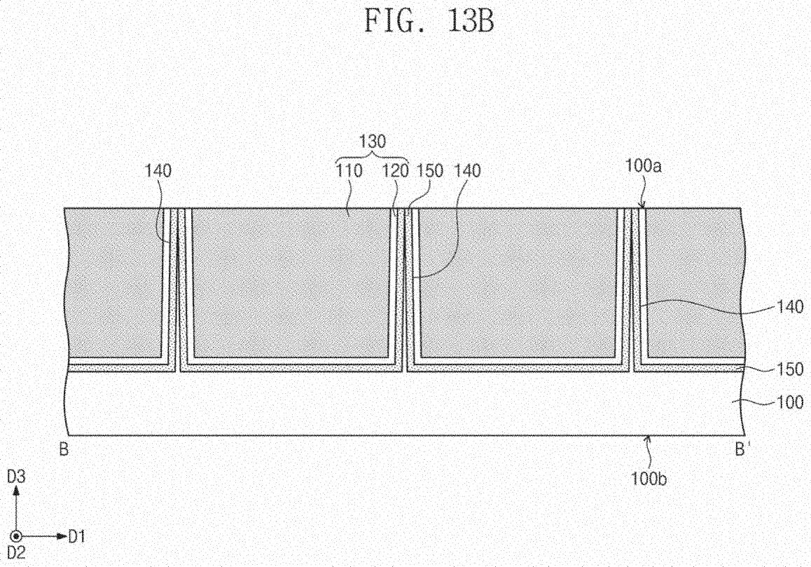

FIG. 11 is a plan view illustrating a method of fabricating an image sensor according to an embodiment, and FIGS. 12A and 12B are sectional views respectively taken along lines A-A′ and B-B′, respectively, of FIG. 11. FIGS. 13A and 13B are sectional views, which are respectively taken along lines A-A′ and B-B′, respectively, of FIG. 9 to illustrate a method of fabricating an image sensor according to an embodiment. For the sake of brevity, repeated description of features which are the same as those of FIGS. 5, 6A to 8A, and 6B to 8B will be omitted for conciseness and features, which are different from the method described with reference to FIGS. 5, 6A to 8A, and 6B to 8B, will be mainly described below.

Referring to FIGS. 11, 12A, and 12B, a plurality of trenches 130T may be formed in a substrate 100 to define a plurality of pixel regions PXR and a plurality of supporting patterns 140. The trenches 130T may be formed by substantially the same method as that described with reference to FIGS. 5, 6A, and 6B. As an example, the trenches 130T may be spaced apart from each other in the first direction D1, between ones of the first and second pixel rows RO1 and RO2 that are adjacent to each other in the second direction D2. Each of the trenches 130T may be extended into regions between adjacent ones of the pixel regions PXR in the first pixel row RO1 and between adjacent ones of the pixel regions PXR in the second pixel row RO2 and may be a cross-shaped pattern, when viewed in a plan view.

The supporting patterns 140 may be formed between the pixel regions PXR. The supporting patterns 140 may be formed to be spaced apart from each other in the first direction D1, between the first and second pixel rows RO1 and RO2. Each of the supporting patterns 140 may be interposed between adjacent ones of the trenches 130T. Each of the supporting patterns 140 may be interposed between a corresponding one of the pixel regions PXR in the first pixel row RO1 and a corresponding one of the pixel region PXR in the second pixel row RO2 and may be connected to the corresponding pixel regions PXR. The supporting patterns 140 may be interposed between adjacent ones of the pixel regions PXR in the first pixel row RO1 and between adjacent ones of the pixel regions PXR in the second pixel row RO2 and may be connected to the adjacent ones of the pixel regions PXR.

A first doped region 150 and a second doped region 152 may be formed in side portions of the supporting patterns 140, side portions of the pixel regions PXR, and the substrate 100 exposed by the trenches 130T.

Referring to FIGS. 9, 13A, and 13B, device isolation patterns 130 may be formed to fill the trenches 130T, respectively. The device isolation patterns 130 may be formed by substantially the same method as that described with reference to FIGS. 2, 7A, and 7B, and thus a repeated description thereof is omitted for conciseness. Subsequent processes may be performed in substantially the same manner as that described with reference to FIGS. 2, 4A, 4B, 8A, and 8B, and thus a repeated description thereof is omitted for conciseness.

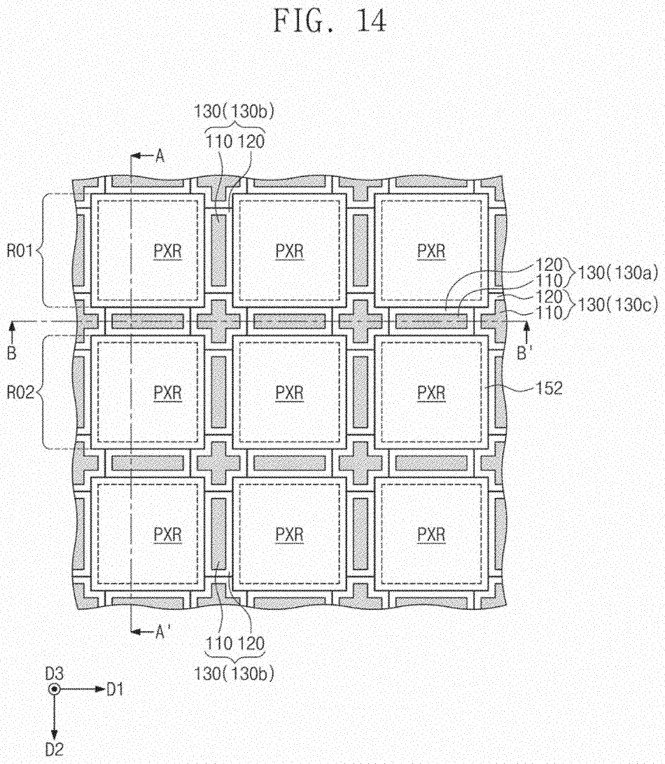

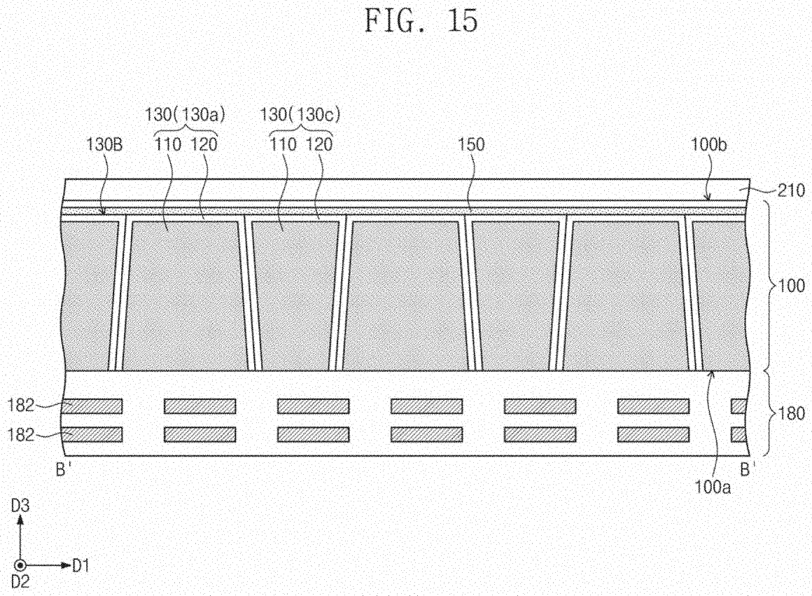

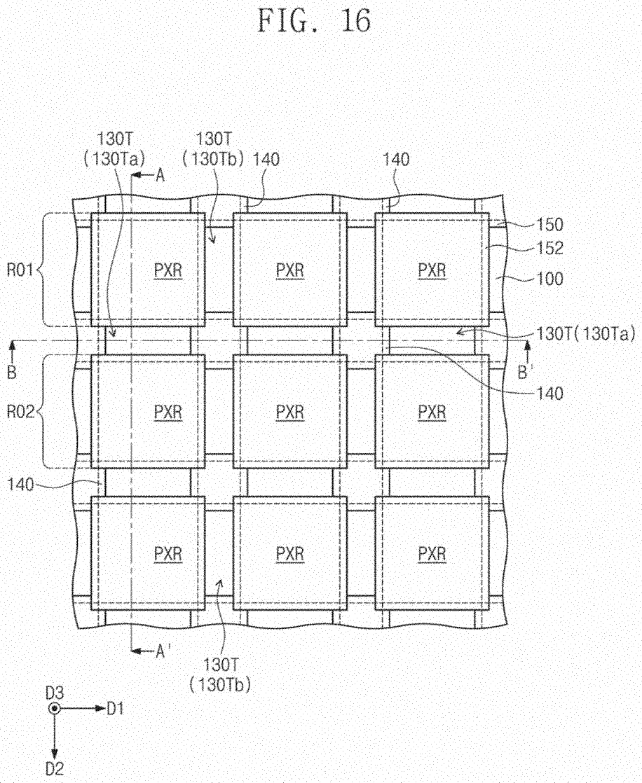

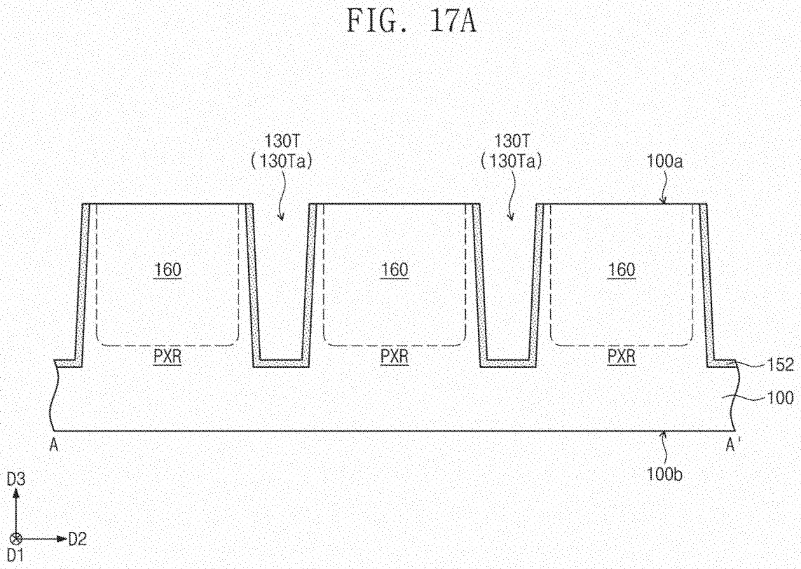

FIG. 14 is a plan view illustrating an image sensor according to an embodiment, and FIG. 15 is a sectional view taken along a line B-B′ of FIG. 14. The sectional view taken along a line A-A′ of FIG. 14 may be substantially the same as that of FIG. 4A, and thus a repeated description thereof is omitted for conciseness. For the sake of brevity, repeated description of features which are the same as those of FIGS. 2, 3, 4A, and 4B will be omitted for conciseness and features, which are different from those of the image sensor of FIGS. 2, 3, 4A, and 4B, will be mainly described below.

Referring to FIGS. 14 and 15 in conjunction with FIG. 4A, device isolation patterns 130 may be disposed in the substrate 100 and between the pixel regions PXR. The device isolation patterns 130 may include first device isolation patterns 130a separated from each other in the first direction D1 and second device isolation patterns 130b separated from each other in the second direction D2. The first device isolation patterns 130a may be disposed between the first and second pixel rows RO1 and RO2 and may be spaced apart from each other in the first direction D1. The second device isolation patterns 130b may be disposed between the pixel regions PXR in the first pixel row RO1 and between the pixel regions PXR in the second pixel row RO2.

The device isolation patterns 130 may further include third device isolation patterns 130c, which are disposed between the first and second pixel rows RO1 and RO2 and are interposed between the first device isolation patterns 130a. The first device isolation patterns 130a and the third device isolation patterns 130c may be alternately and repeatedly arranged in the first direction D1, between the first and second pixel rows RO1 and RO2. Each of the third device isolation patterns 130c may be interposed between a corresponding pair of the second device isolation patterns 130b. Each of the third device isolation patterns 130c may be interposed between directly adjacent ones of the first device isolation patterns 130a and between directly adjacent ones of the second device isolation patterns 130b.

Each of the device isolation patterns 130 may include an isolation pattern 110, which is provided to penetrate at least a portion of the substrate 100, and an insulating pattern 120, which is interposed between the isolation pattern 110 and the substrate 100. The isolation pattern 110 may be disposed between adjacent ones of the pixel regions PXR, and the insulating pattern 120 may be interposed between the isolation pattern 110 and each of the adjacent ones of the pixel regions PXR. The isolation pattern 110 of each of the first and second device isolation patterns 130a and 130b may be disposed between adjacent ones of the third device isolation patterns 130c. The insulating pattern 120 of each of the first and second device isolation patterns 130a and 130b may be extended into a region between the isolation pattern 110 and each of the adjacent ones of the third device isolation patterns 130c. The isolation pattern 110 of each of the third device isolation patterns 130c may be disposed between adjacent ones of the first device isolation patterns 130a and between adjacent ones of the second device isolation patterns 130b. The insulating pattern 120 of each of the third device isolation patterns 130c may be extended into a region between the isolation pattern 110 and each of the adjacent ones of the first and second device isolation patterns 130a and 130b.

In the present specification, the isolation pattern 110 and the insulating pattern 120 of each of the first device isolation patterns 130a may be referred to as a first isolation pattern 110 and a first insulating pattern 120, respectively, and the isolation pattern 110 and the insulating pattern 120 of each of the second device isolation patterns 130b may be referred to as a second isolation pattern 110 and a second insulating pattern 120, respectively. In addition, the isolation pattern 110 and the insulating pattern 120 of each of the third device isolation patterns 130c may be referred to as a third isolation pattern 110 and a third insulating pattern 120, respectively.

In some embodiments, a first doped region 150 may be disposed in the substrate 100 that is adjacent to bottom surfaces 130B of the device isolation patterns 130. A second doped region 152 may be disposed in each of the pixel regions PXR and may be extended along a side surface of each of the pixel regions PXR. In some embodiments, the second doped region 152 may be extended into a portion of the substrate 100, which is adjacent to the bottom surface 130B of each of the device isolation patterns 130, and may be connected to the first doped region 150.

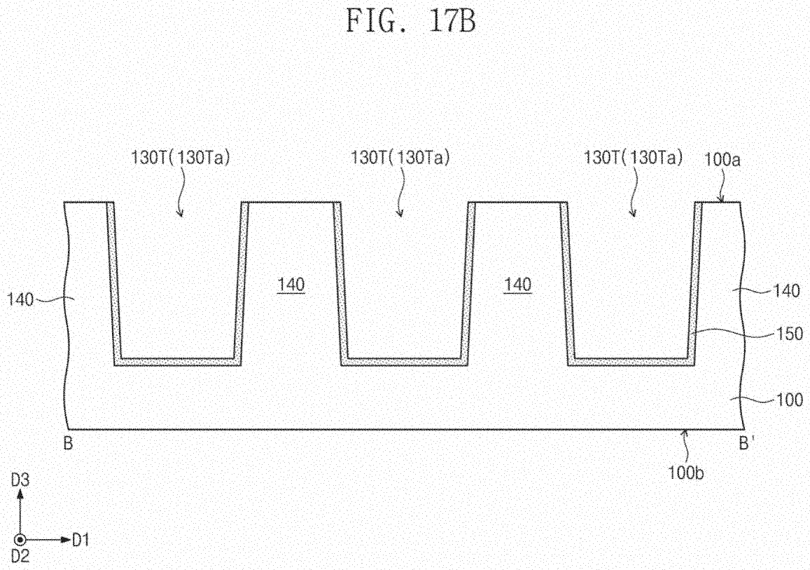

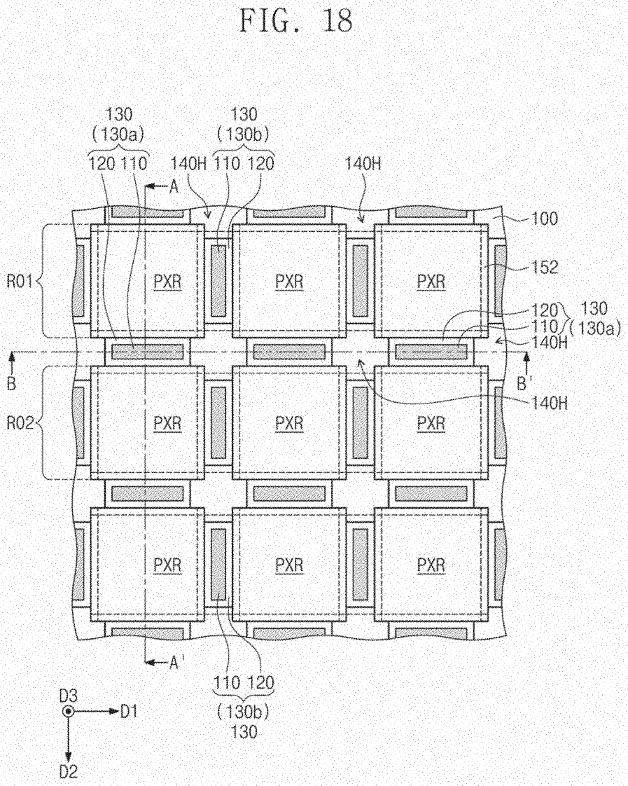

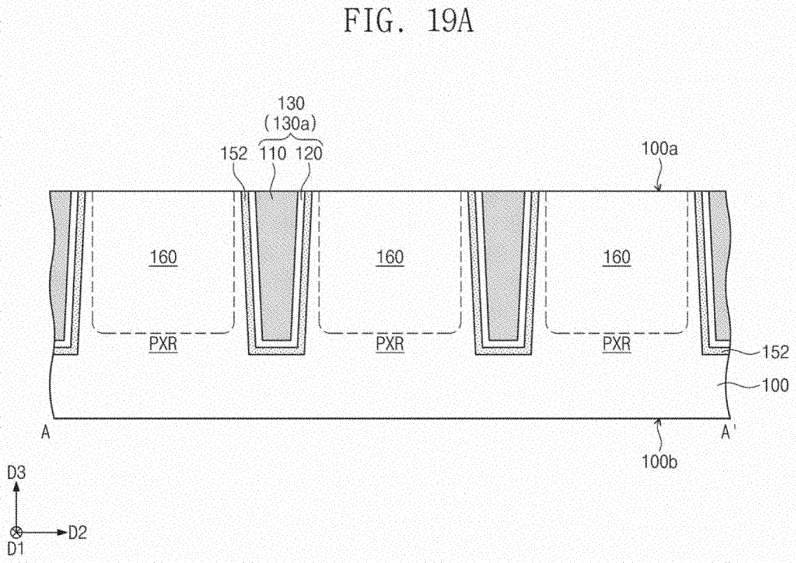

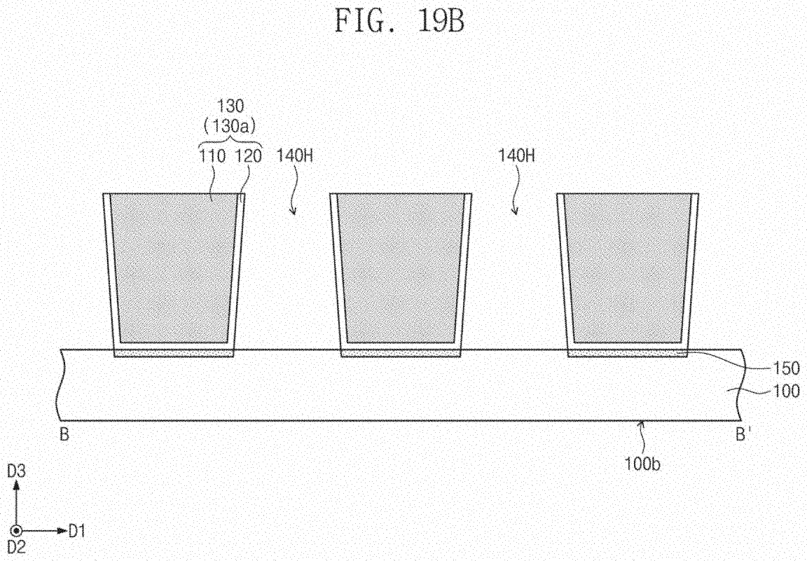

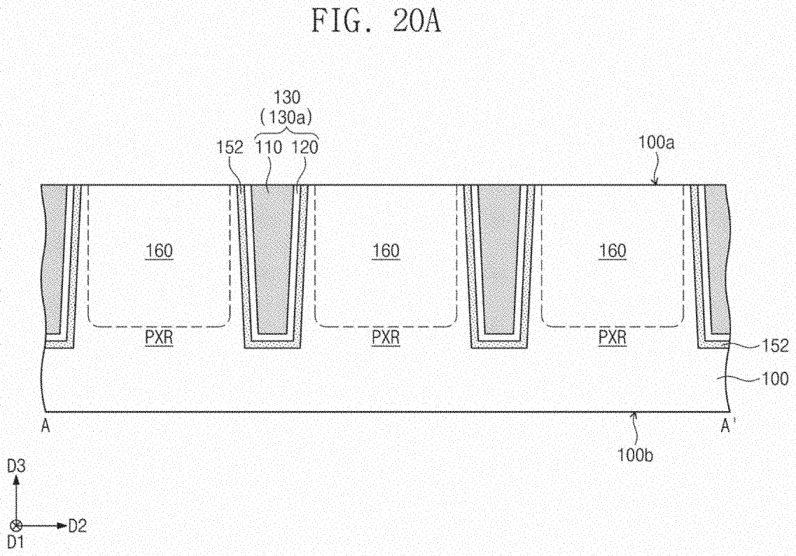

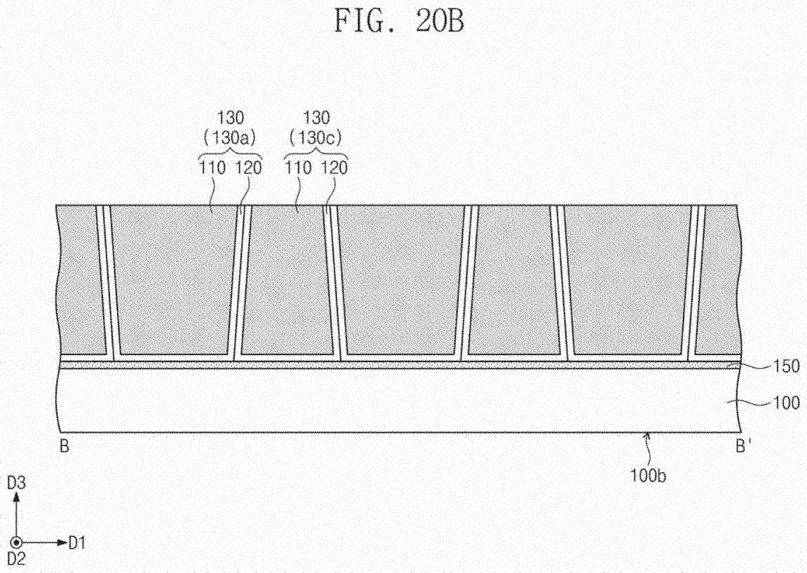

FIGS. 16 and 18 are plan views illustrating a method of fabricating an image sensor according to an embodiment. FIGS. 17A and 17B are sectional views respectively taken along lines A-A′ and B-B′ of FIG. 16, and FIGS. 19A and 19B are sectional views respectively taken along lines A-A′ and B-B′ of FIG. 18. FIGS. 20A and 20B are sectional views, which are respectively taken along lines A-A′ and B-B′ of FIG. 14 to illustrate a method of fabricating an image sensor according to an embodiment. For the sake of brevity, repeated description of features which are the same as those of FIGS. 5, 6A to 8A, and 6B to 8B will be omitted for conciseness and features, which are different from the method of FIGS. 5, 6A to 8A, and 6B to 8B, will be mainly described below.

Referring to FIGS. 16, 17A, and 17B, a plurality of trenches 130T may be formed in a substrate 100 to define a plurality of pixel regions PXR and a plurality of supporting patterns 140. The trenches 130T may be formed by substantially the same method as that described with reference to FIGS. 5, 6A, and 6B. The trenches 130T may include first trenches 130Ta, which are spaced apart from each other in the first direction D1, and second trenches 130Tb, which are spaced apart from each other in the second direction D2. The first trenches 130Ta may be spaced apart from each other in the first direction D1, between first and second pixel rows RO1 and RO2. The second trenches 130Tb may be formed between pixel regions PXR in the first pixel row RO1 and between pixel regions PXR in the second pixel row RO2.

The supporting patterns 140 may be formed between the pixel regions PXR. The supporting patterns 140 may be formed between the first and second pixel rows RO1 and RO2 to be spaced apart from each other in the first direction D1. Each of the supporting patterns 140 may be interposed between adjacent ones of the first trenches 130Ta and between adjacent ones of the second trenches 130Tb. Each of the supporting patterns 140 may be connected to corresponding ones of the pixel regions PXR. As an example, each of the supporting patterns 140 may be disposed between and connected to four directly adjacent ones of the pixel regions PXR, as best seen in FIG. 16.

A first doped region 150 may be formed on side surfaces of the supporting patterns 140 exposed by the trenches 130T and in a portion of the substrate 100 adjacent to bottom surfaces of the trenches 130T. A second doped region 152 may be formed on side surfaces of the pixel regions PXR exposed by the trenches 130T and in a portion of the substrate 100 adjacent to the bottom surfaces of the trenches 130T.

Referring to FIGS. 18, 19A, and 19B, device isolation patterns 130 may be formed to fill the trenches 130T, respectively. The device isolation patterns 130 may be formed by substantially the same method as that described with reference to FIGS. 2, 7A, and 7B, and thus repeated description thereof will be omitted for conciseness. Each of the device isolation patterns 130 may include an isolation pattern 110, which is disposed in each of the trenches 130T, and an insulating pattern 120, which is interposed between an inner surface of each of the trenches 130T and the isolation pattern 110. The device isolation patterns 130 may include first device isolation patterns 130a filling the first trenches 130Ta and second device isolation patterns 130b filling the second trenches 130Tb.

The supporting patterns 140 may be removed, after the formation of the first and second device isolation patterns 130a and 130b. In an embodiment, the removal of the supporting patterns 140 may include forming a mask pattern (not shown) on the first surface 100a of the substrate 100 to have openings exposing the supporting patterns 140 and etching the supporting patterns 140 using the mask pattern as an etch mask. The insulating pattern 120 of each of the device isolation patterns 130 may be used as an etch stop layer, during the etching of the supporting patterns 140. As a result of the etching of the supporting patterns 140, a plurality of holes 140H may be formed between the pixel regions PXR and between the device isolation patterns 130. Each of the holes 140H may be formed between adjacent ones of the first device isolation patterns 130a and between adjacent ones of the second device isolation patterns 130b.

Referring to FIGS. 14, 20A, and 20B, third device isolation patterns 130c may be formed to fill the holes 140H, respectively. The third device isolation patterns 130c may be formed by substantially the same method as that described with reference to FIGS. 2, 7A, and 7B, and thus repeated description thereof will be omitted for conciseness. Each of the third device isolation patterns 130c may include an isolation pattern 110, which is disposed in each of the holes 140H, and an insulating pattern 120, which is interposed between the isolation pattern 110 and an inner surface of each of the holes 140H. In some embodiments, before the forming of the third device isolation patterns 130c, an additional doped region may be formed in the substrate 100 exposed by the holes 140H. Accordingly, the first doped region 150 may be extended along bottom surfaces 130B of the first to third device isolation patterns 130a, 130b, and 130c. Subsequent processes may be performed in substantially the same manner as that described with reference to FIGS. 2, 4A, 4B, 8A, and 8B, and thus repeated description thereof will be omitted for conciseness.

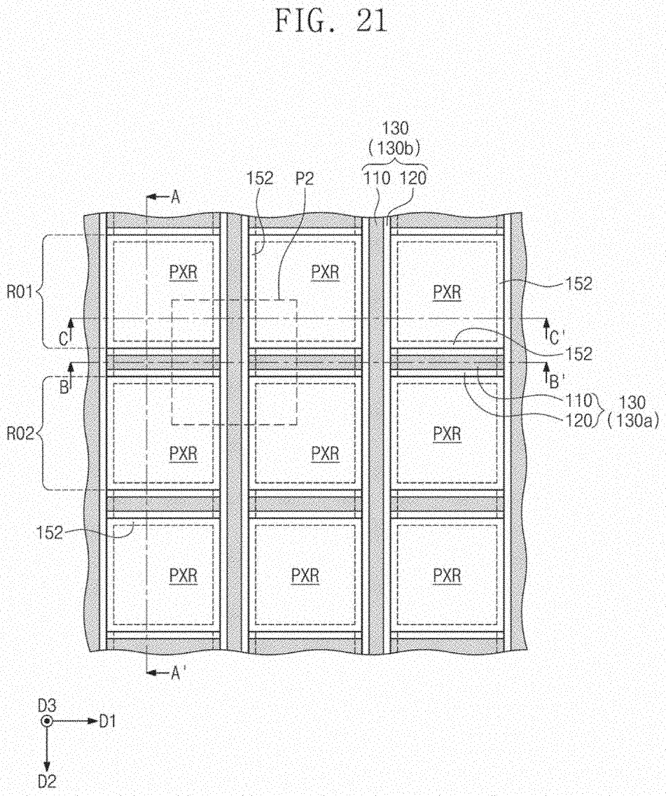

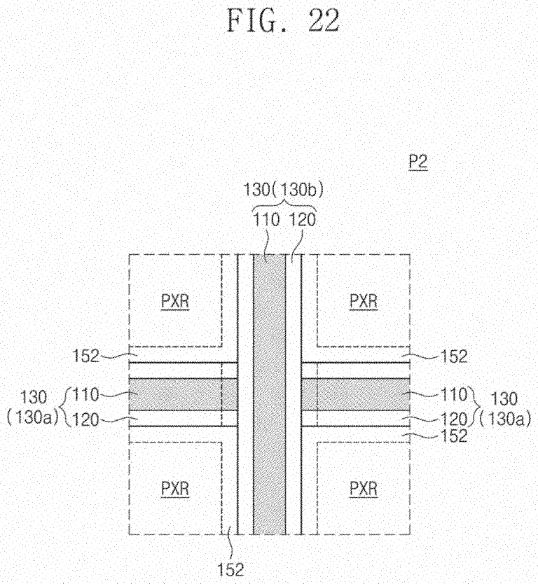

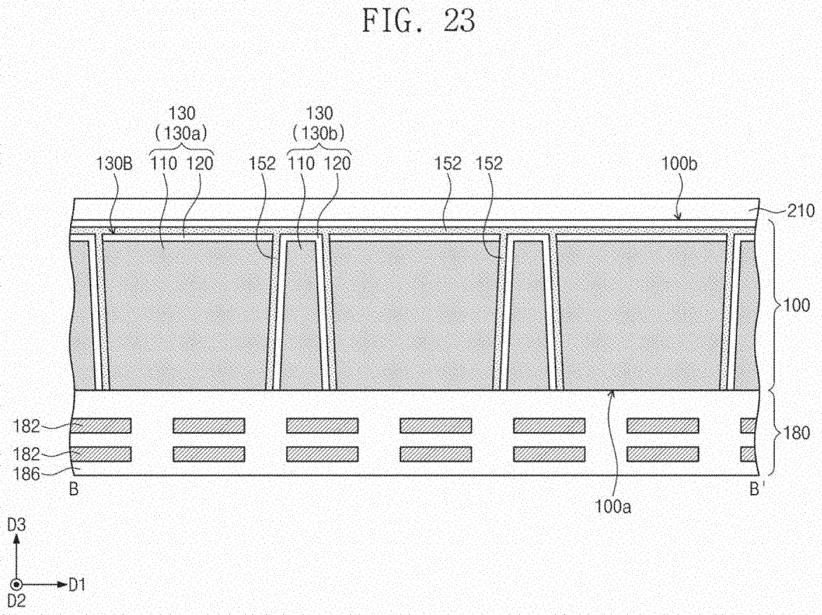

FIG. 21 is a plan view illustrating an image sensor according to an embodiment, and FIG. 22 is an enlarged view illustrating a portion P2 of the image sensor of FIG. 21. FIG. 23 is a sectional view taken along a line B-B′ of FIG. 21. The sectional views taken along lines A-A′ and C-C′ of FIG. 21 may be substantially the same as those of FIG. 4A, and thus repeated description thereof will be omitted for conciseness. For the sake of brevity, repeated description of features which are the same as those of FIGS. 2, 3, 4A, and 4B will be omitted for conciseness and features, which are different from those of the image sensor of FIGS. 2, 3, 4A, and 4B, will be mainly described below.

Referring to FIGS. 21, 22 and 23 in conjunction with FIG. 4A, device isolation patterns 130 may be disposed in the substrate 100 and between the pixel regions PXR. The device isolation patterns 130 may include first device isolation patterns 130a, which are spaced apart from each other in the first direction D1, and second device isolation patterns 130b, which are interposed between the first device isolation patterns 130a and are extended in the second direction D2. The first device isolation patterns 130a may be disposed between the first and second pixel rows RO1 and RO2 and may be spaced apart from each other in the first direction D1. Each of the second device isolation patterns 130b may be interposed between adjacent ones of the first device isolation patterns 130a and may be extended parallel to the second direction D2 and into regions between adjacent ones of the pixel regions PXR in the first pixel row RO1 and between adjacent ones of the pixel regions PXR in the second pixel row RO2.

Each of the device isolation patterns 130 may include an isolation pattern 110, which is provided to penetrate at least a portion of the substrate 100, and an insulating pattern 120, which is interposed between the isolation pattern 110 and the substrate 100. The isolation pattern 110 may be disposed between adjacent ones of the pixel regions PXR, and the insulating pattern 120 may be interposed between the isolation pattern 110 and each of the adjacent ones of the pixel regions PXR. The isolation and insulating patterns 110 and 120 of each of the first device isolation patterns 130a may be disposed between adjacent ones of the second device isolation patterns 130b.

The isolation pattern 110 of each of the second device isolation patterns 130b may be interposed between adjacent ones of the first device isolation patterns 130a and may be extended parallel to the second direction D2 and into regions between adjacent ones of the pixel regions PXR in the first pixel row RO1 and between adjacent ones of the pixel regions PXR in the second pixel row RO2. The insulating pattern 120 of each of the second device isolation patterns 130b may be interposed between the isolation pattern 110 and each of the adjacent ones of the first device isolation patterns 130a and may be extended parallel to the second direction D2 and into regions between the isolation pattern 110 and each of the adjacent ones of the pixel regions PXR.

A doped region 152 may be disposed in each of the pixel regions PXR and may be extended along a side surface of each of the pixel regions PXR. In some embodiments, the doped region 152 may be extended into a portion of the substrate 100 that is adjacent to the bottom surface 130B of each of the device isolation patterns 130. The doped region 152 may be extended along a side surface of each of the second device isolation patterns 130b and in the second direction D2, and thus, the doped region 152 may be disposed in the isolation pattern 110 of each of the first device isolation patterns 130a. The doped region 152 may be interposed between the insulating pattern 120 of each of the second device isolation patterns 130b and a pixel region PXR adjacent thereto and between the insulating pattern 120 of each of the second device isolation patterns 130b and the isolation pattern 110 of the first device isolation patterns 130a adjacent thereto.

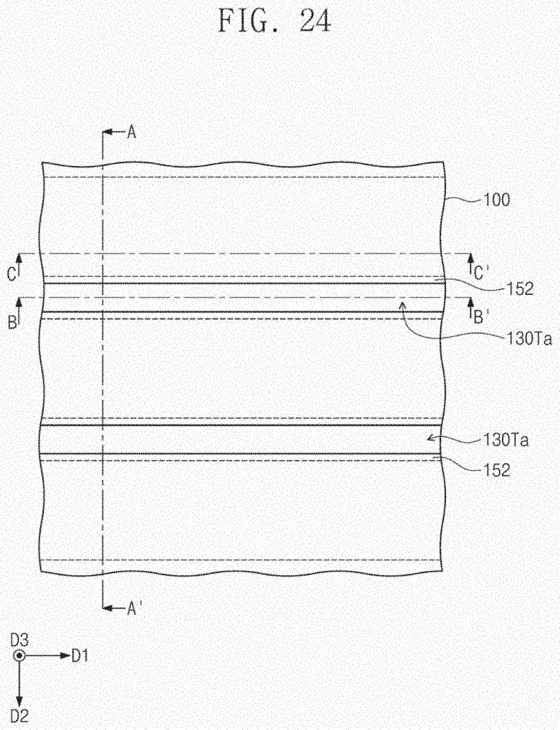

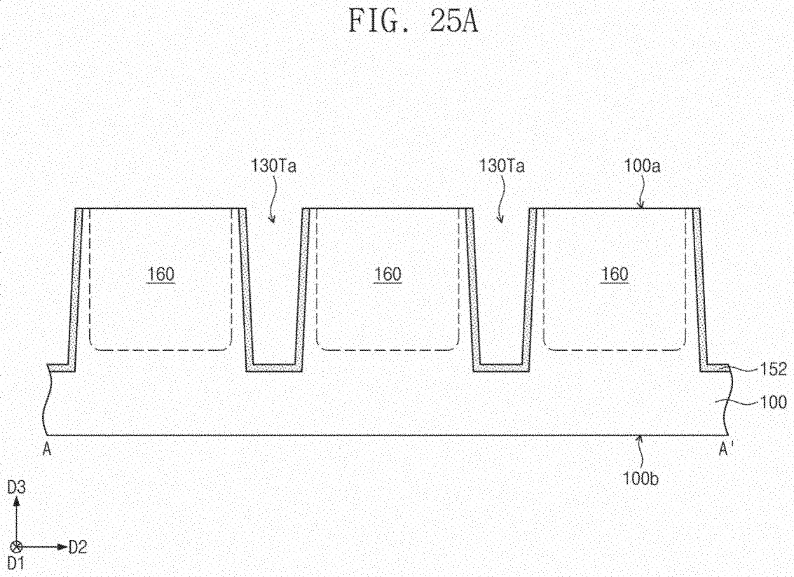

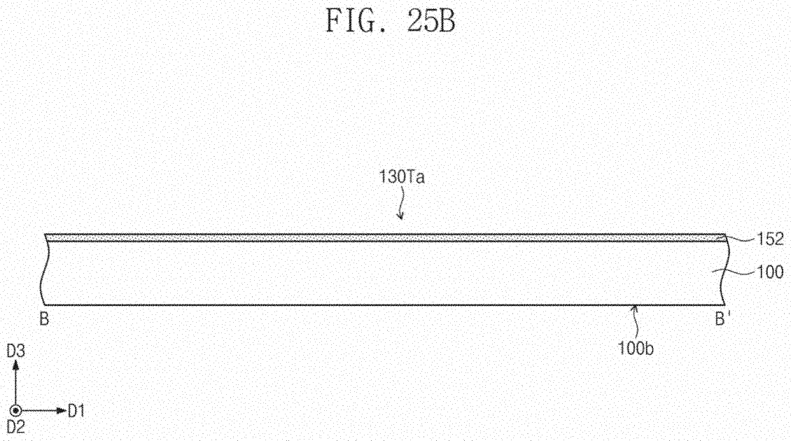

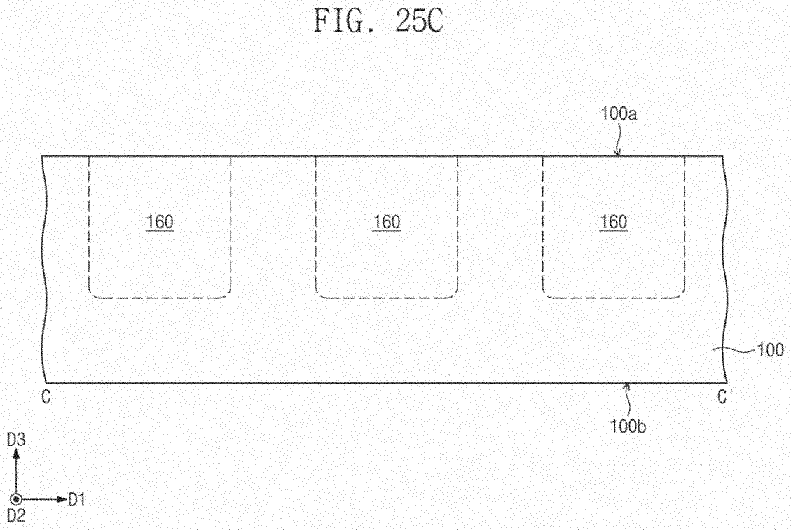

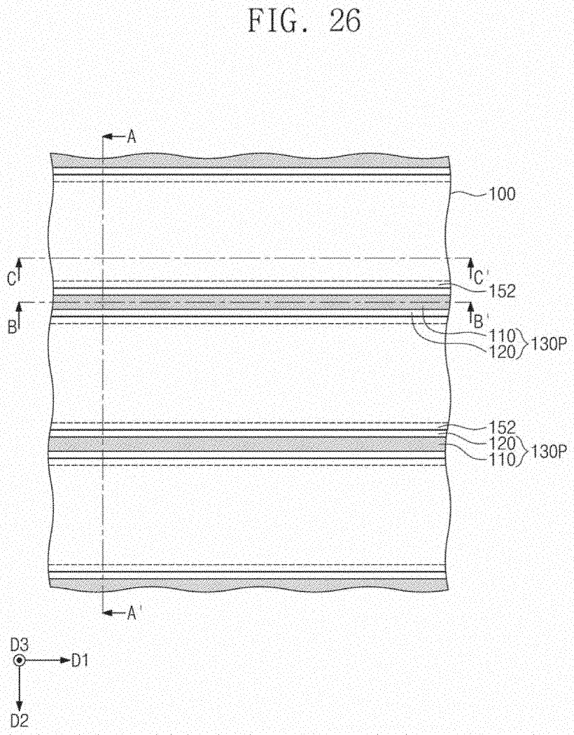

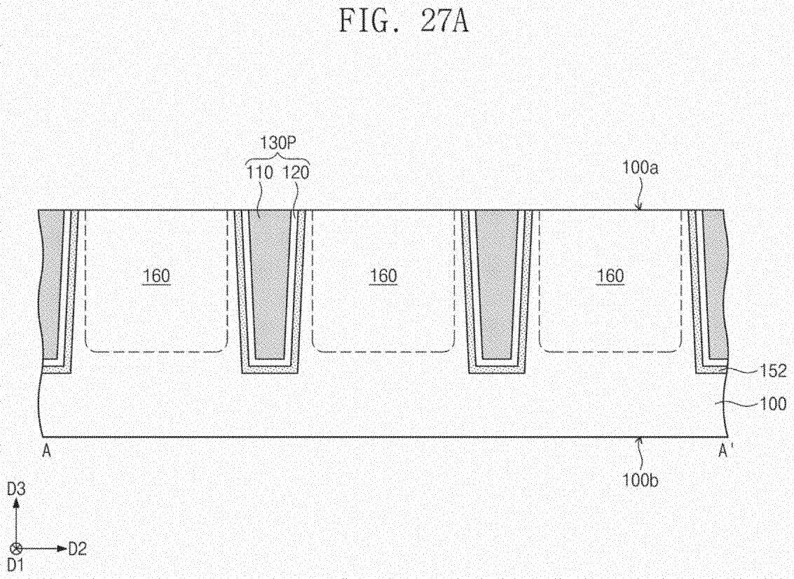

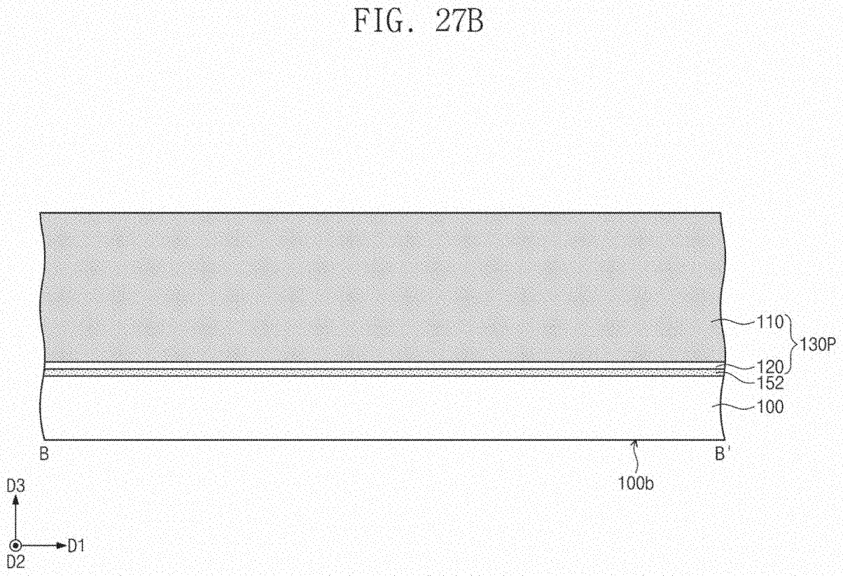

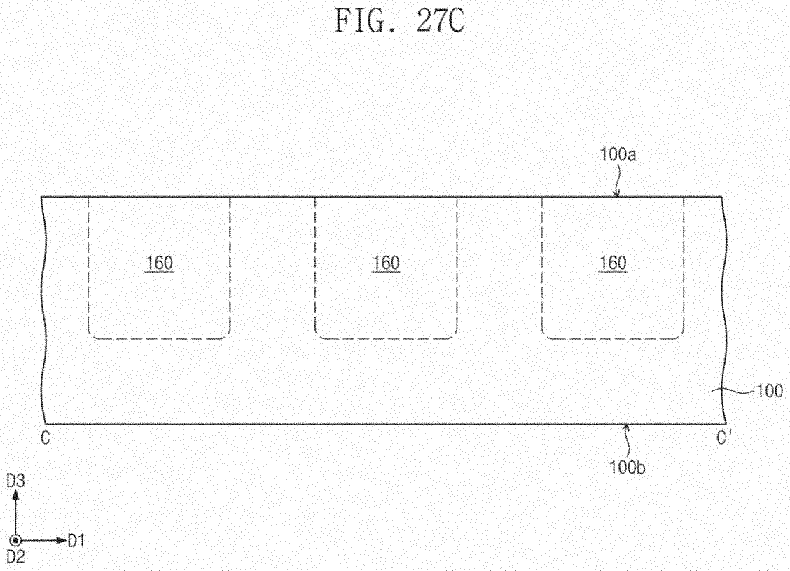

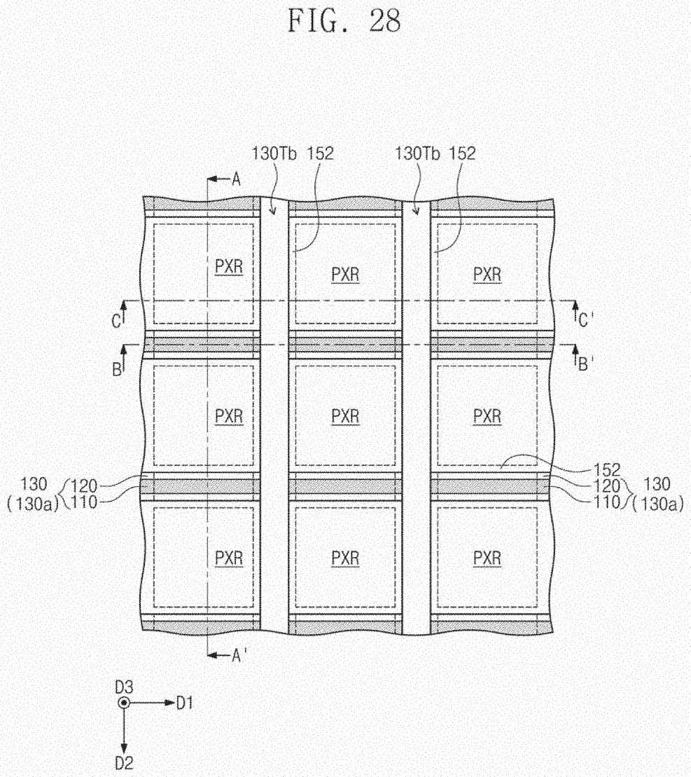

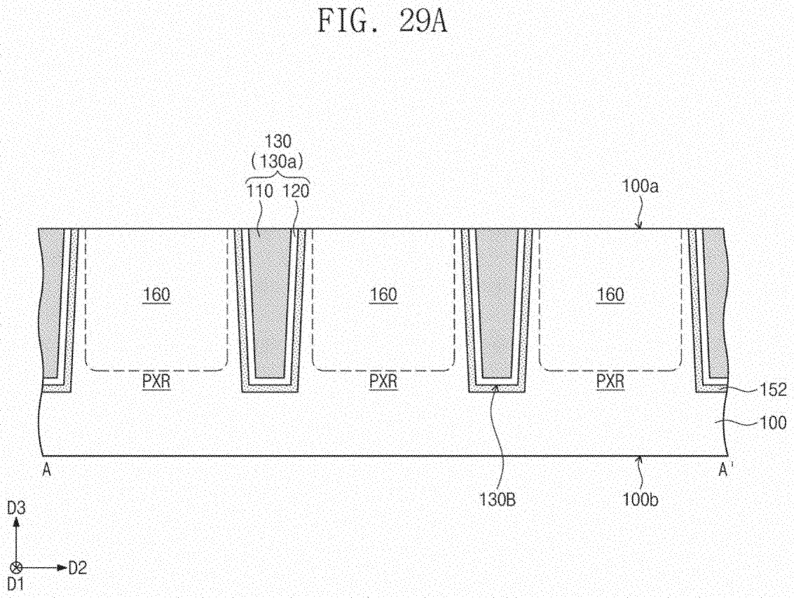

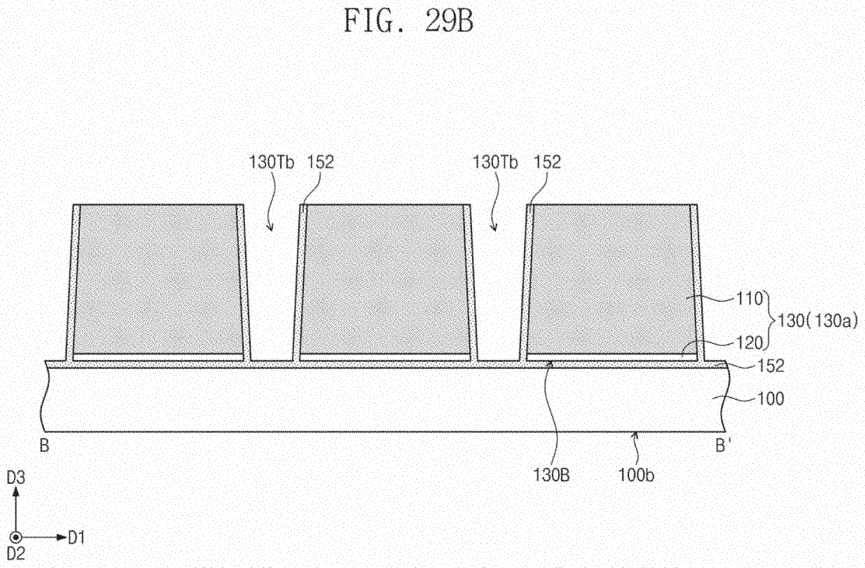

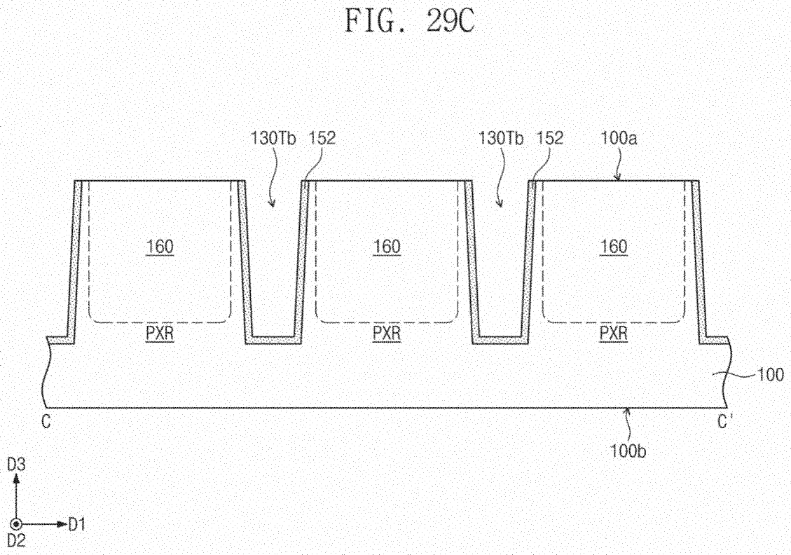

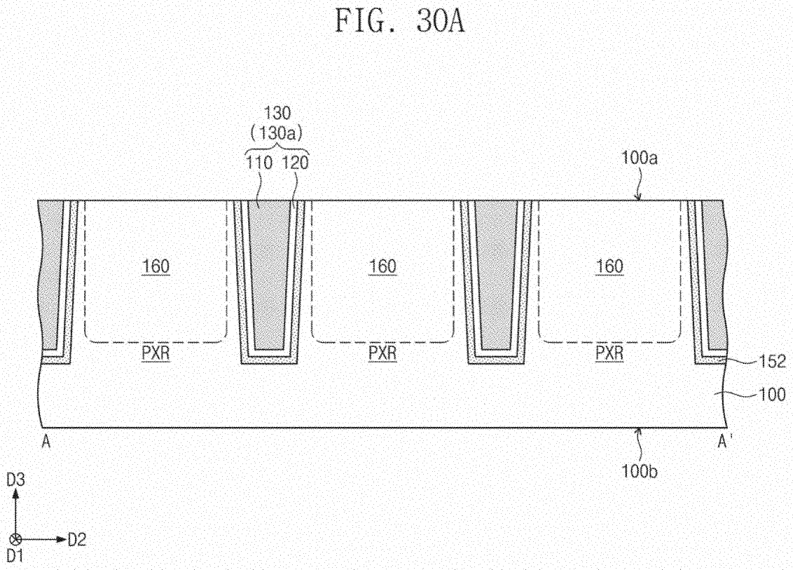

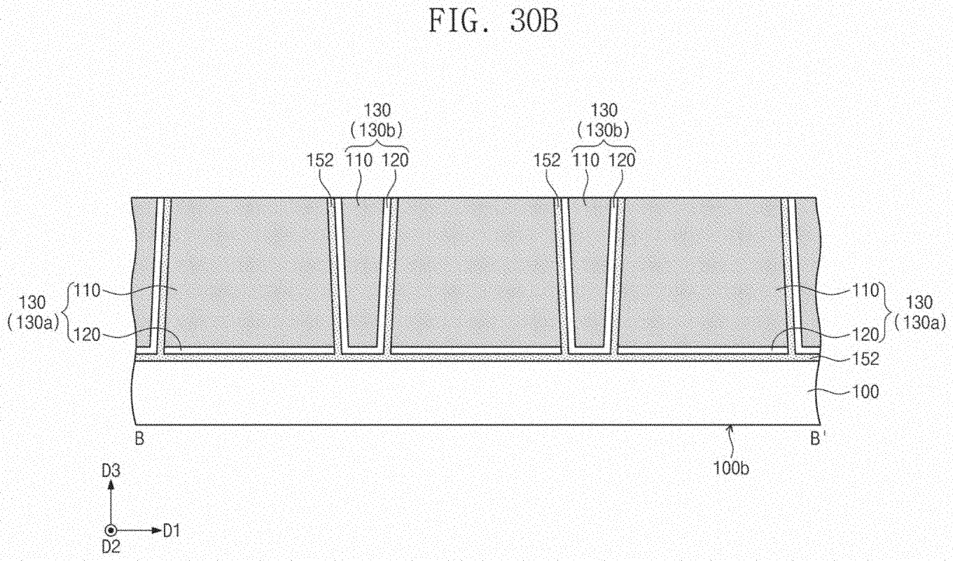

FIGS. 24, 26, and 28 are plan views illustrating a method of fabricating an image sensor according to an embodiment. FIGS. 25A to 25C are sectional views respectively taken along lines A-A′, B-B′, and C-C′ of FIG. 24, FIGS. 27A to 27C are sectional views respectively taken along lines A-A′, B-B′, and C-C′ of FIG. 26, and FIGS. 29A to 29C are sectional views respectively taken along lines A-A′, B-B′, and C-C′ of FIG. 28. FIGS. 30A to 30C are sectional views, which are respectively taken along lines A-A′, B-B′, and C-C′ of FIG. 21 to illustrate a method of fabricating an image sensor according to an embodiment. For the sake of brevity, repeated description of features which are the same as those of FIGS. 5, 6A to 8A, and 6B to 8B will be omitted for conciseness and features, which are different from the method of FIGS. 5, 6A to 8A, and 6B to 8B, will be mainly described below.

Referring to FIGS. 24 and 25A to 25C, first trenches 130Ta may be formed in a substrate 100. The first trenches 130Ta may be extended in the first direction D1 and may be spaced apart from each other in the second direction D2. The formation of the first trenches 130Ta may include forming a first mask pattern (not shown) on the first surface 100a of the substrate 100 to have openings exposing regions, in which the first trenches 130Ta will be formed, and etching the substrate 100 using the first mask pattern as an etch mask.

First impurity regions 160 may be formed in the substrate 100 between the first trenches 130Ta, and a doped region 152 may be formed in side and bottom surfaces of the substrate 100 exposed by the first trenches 130Ta. The doped region 152 may be formed in a portion of the substrate 100 that is adjacent to inner side surfaces and bottom surfaces of the first trenches 130Ta. The first impurity regions 160 and the doped region 152 may be formed by substantially the same method as that described with reference to FIGS. 5, 6A, and 6B, and thus repeated description thereof will be omitted for conciseness.

Referring to FIGS. 26 and 27A to 27C, preliminary device isolation patterns 130P may be formed to fill the first trenches 130Ta, respectively. The preliminary device isolation patterns 130P may be formed by substantially the same method as that described with reference to FIGS. 2, 7A, and 7B, and thus repeated description thereof will be omitted for conciseness. Each of the preliminary device isolation patterns 130P may include an isolation pattern 110, which is disposed in each of the first trenches 130Ta, and an insulating pattern 120, which is interposed between an inner surface of each of the first trenches 130Ta and the isolation pattern 110.

Referring to FIGS. 28 and 29A to 29C, second trenches 130Tb may be formed in the substrate 100. The second trenches 130Tb may be formed to cross the first trenches 130Ta. As an example, the second trenches 130Tb may be extended in the second direction D2 and may be spaced apart from each other in the first direction D1. The formation of the second trenches 130Tb may include forming a second mask pattern (not shown) on the first surface 100a of the substrate 100 to have openings exposing regions, in which the second trenches 130Tbwill be formed, and etching the substrate 100 and the preliminary device isolation patterns 130P using the second mask pattern as an etch mask.

Each of the preliminary device isolation patterns 130P may be divided into first device isolation patterns 130a, which are spaced apart from each other in the first direction D1, by the second trenches 130Tb. The substrate 100 may include a plurality of pixel regions PXR defined by the first and second trenches 130Ta and 130Tb. The pixel regions PXR may be two-dimensionally arranged in the first direction D1 and the second direction D2, as best seen in FIG. 28.

An additional doped region 152 may be formed in side surfaces of the pixel regions PXR, side surfaces of the isolation pattern 110 of each of the first device isolation patterns 130a, and the substrate 100 exposed by the second trenches 130Tb. The additional doped region 152 may be formed by substantially the same method as that described with reference to FIGS. 5, 6A, and 6B, and thus repeated description thereof will be omitted for conciseness. As a result the formation of the additional doped region 152, the doped region 152 may be formed on a side surface of each of the pixel regions PXR and may be extended onto the side surfaces of the isolation pattern 110 of each of the first device isolation patterns 130a. In addition, the doped region 152 may be extended into a portion of the substrate 100 that is adjacent to the bottom surface 130B of each of the first device isolation patterns 130a.

Referring to FIGS. 21 and 30A to 30C, second device isolation patterns 130b may be formed to fill the second trenches 130Tb, respectively. The second device isolation patterns 130b may be formed by substantially the same method as that described with reference to FIGS. 2, 7A, and 7B, and thus repeated description thereof will be omitted for conciseness. Each of the second device isolation patterns 130b may include an isolation pattern 110, which is disposed in each of the second trenches 130Tb, and an insulating pattern 120, which is interposed between the isolation pattern 110 and an inner surface of each of the second trenches 130Tb. Subsequent processes may be performed in substantially the same manner as that described with reference to FIGS. 2, 4A, 4B, 8A, and 8B, and thus repeated description thereof will be omitted for conciseness.

According to an embodiment, after the formation of the first trenches 130Ta, the second trenches 130Tb may be formed to cross the first trenches 130Ta. The pixel regions PXR may be defined by the first and second trenches 130Ta and 130Tb. In this case, since the first and second trenches 130Ta and 130Tb are formed by separate etching processes, it may be possible to prevent a leaning issue of the pixel regions PXR. Accordingly, it may be possible to reduce a process failure in a process of fabricating the image sensor. In addition, since the first and second trenches 130Ta and 130Tb are formed by separate etching processes, the aspect ratio of the pixel regions PXR may be easily increased. This may facilitate the improvement of resolution and sensitivity characteristics of the image sensor.

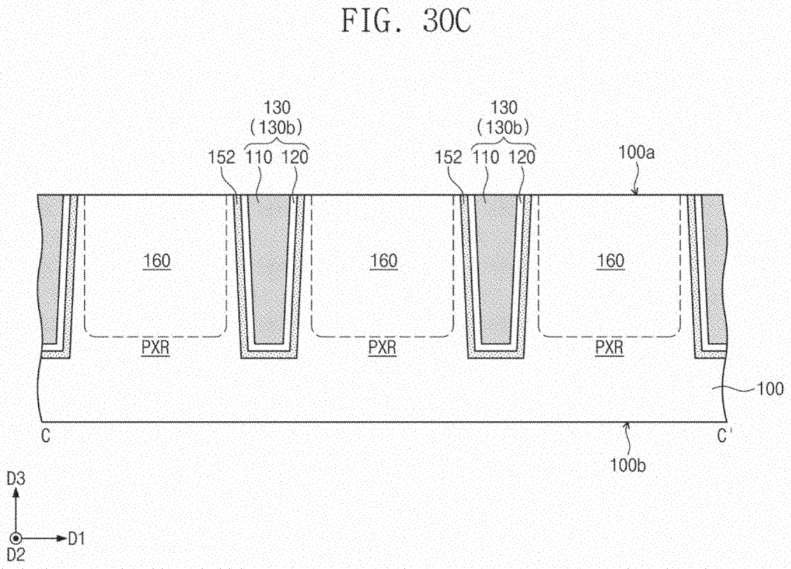

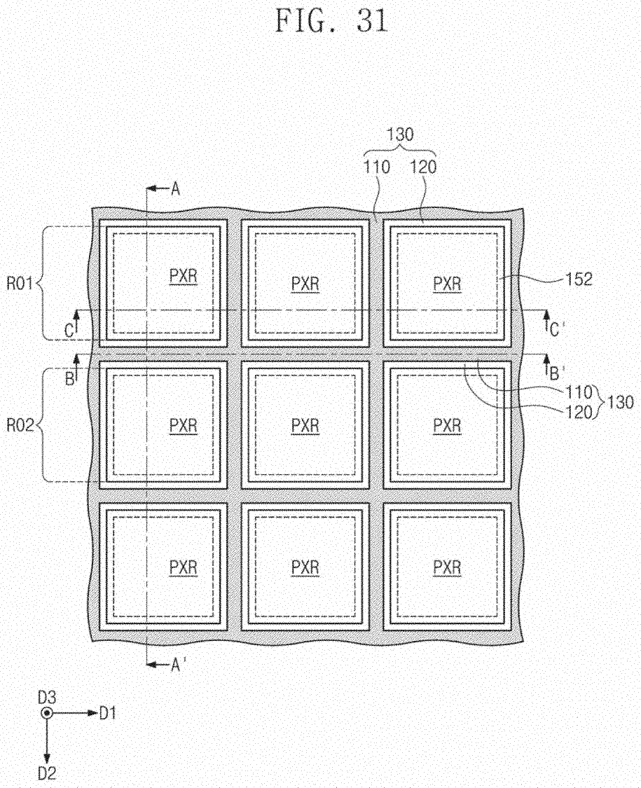

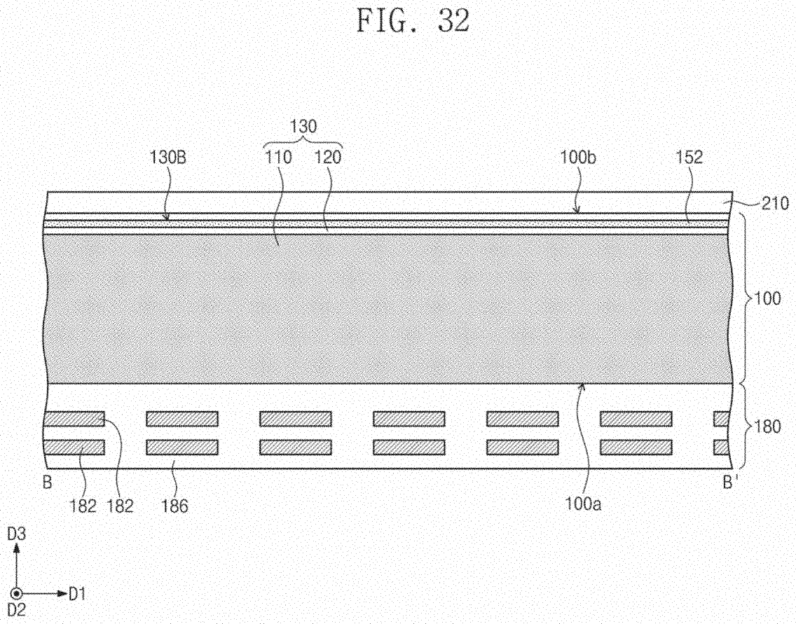

FIG. 31 is a plan view illustrating an image sensor according to an embodiment, and FIG. 32 is a sectional view taken along a line B-B′ of FIG. 31. The sectional views taken along lines A-A′ and C-C′ of FIG. 31 may be substantially the same as those of FIG. 21, and thus repeated description thereof will be omitted for conciseness. For the sake of brevity, repeated description of features which are the same as those of FIGS. 2, 3, 4A, and 4B will be omitted for conciseness and features, which are different from those of the image sensor of FIGS. 2, 3, 4A, and 4B, will be mainly described below.

Referring to FIGS. 31 and 32 in conjunction with FIG. 4A, device isolation layer 130 may be disposed in the substrate 100 and between the pixel regions PXR. The device isolation layer 130 may be extended in the first direction D1, between the first and second pixel rows RO1 and RO2, and may be extended in the second direction D2 to be interposed between adjacent ones of the pixel regions PXR in the first pixel row RO1 and between adjacent ones of the pixel regions PXR in the second pixel row RO2. The portions of the device isolation layer 130 extended in the first and second directions D1 and D2 may be connected to form a single object. The device isolation layer 130 may include an isolation pattern 110, which is provided to penetrate at least a portion of the substrate 100, and an insulating pattern 120, which is interposed between the isolation pattern 110 and the substrate 100.

A doped region 152 may be disposed in each of the pixel regions PXR and may be extended along a side surface of each of the pixel regions PXR. In some embodiments, the doped region 152 may be extended into a portion of the substrate 100 that is adjacent to a bottom surface 130B of the device isolation layer 130. The insulating pattern 120 may be interposed between the isolation pattern 110 and the doped region 152 and may be in contact with the doped region 152.

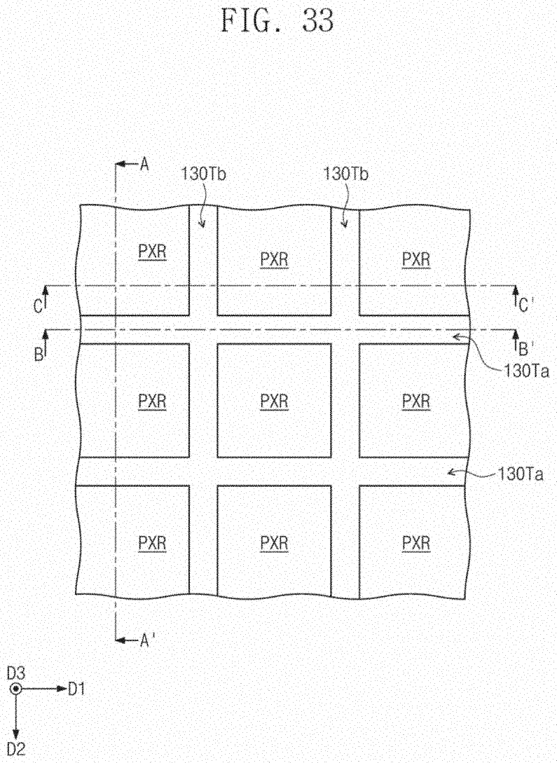

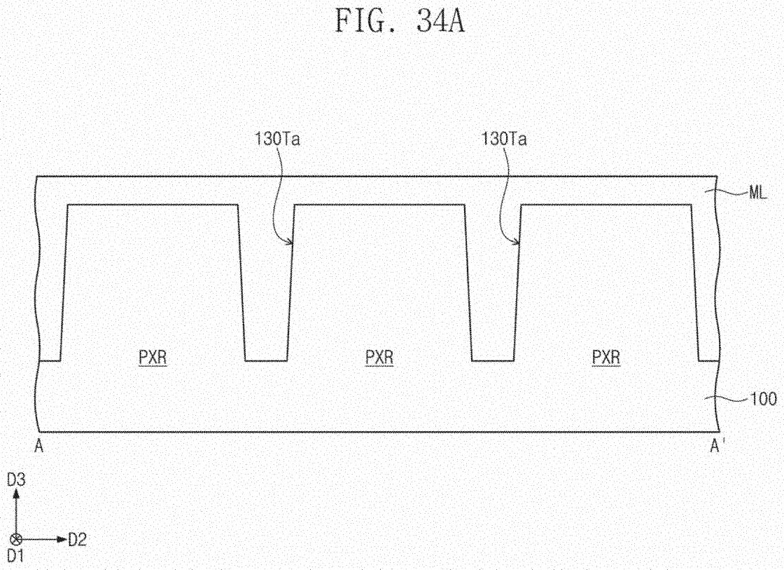

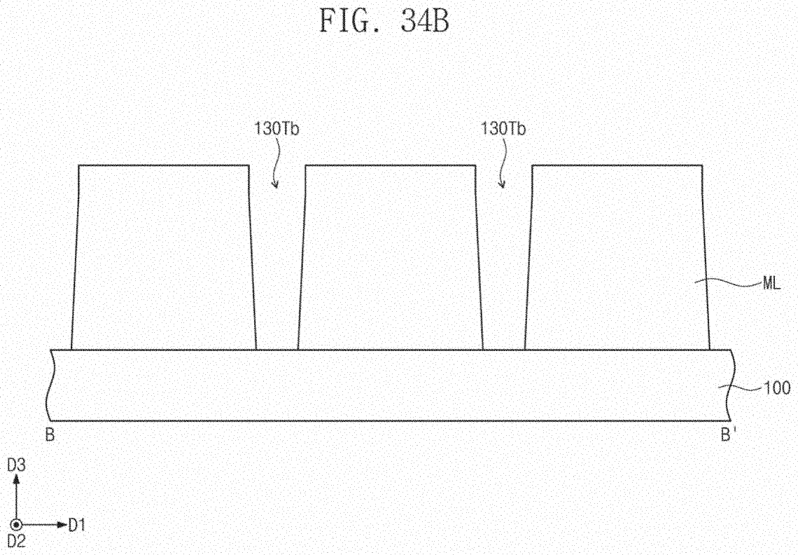

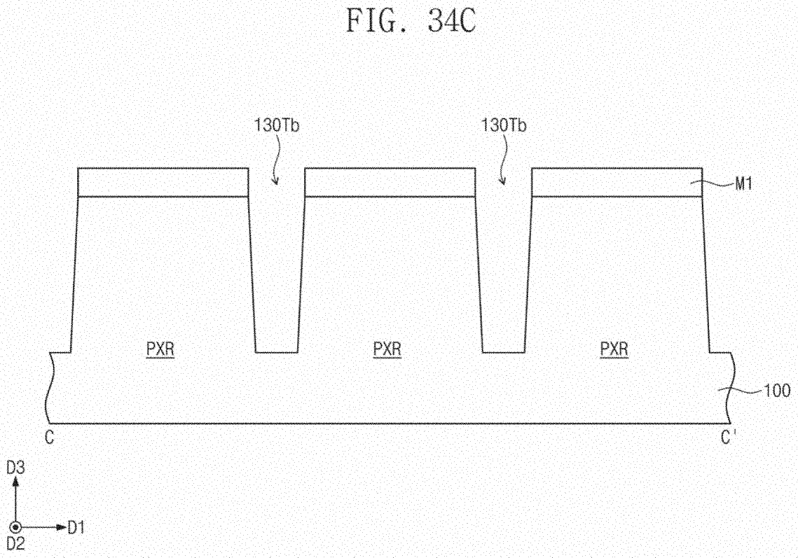

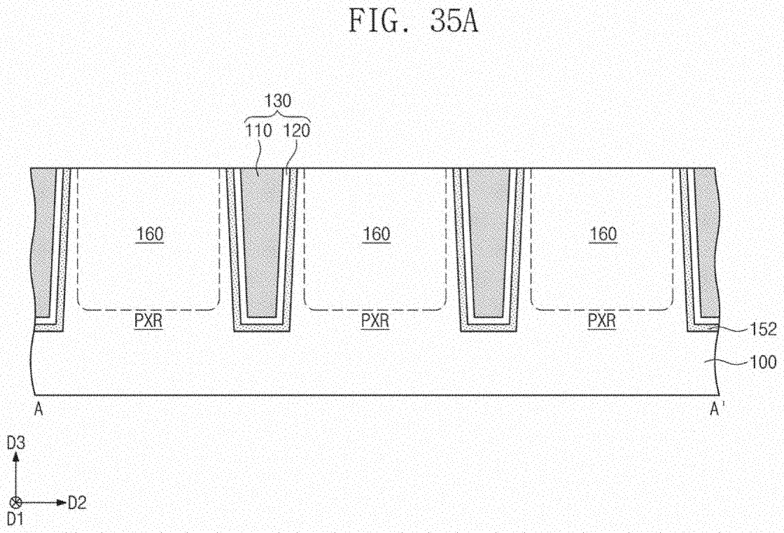

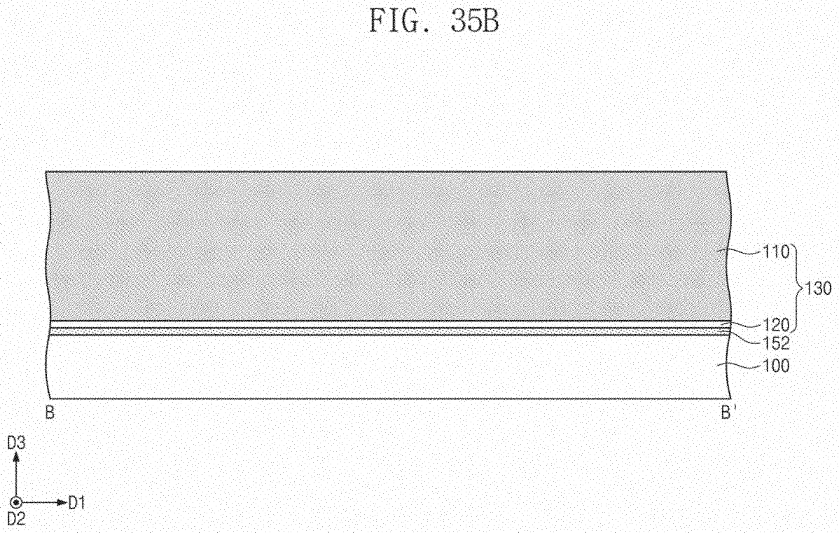

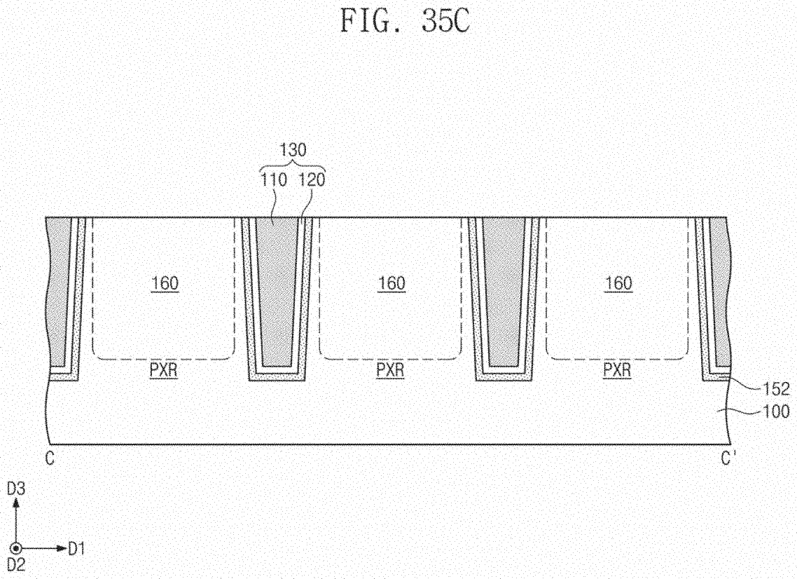

FIG. 33 is a plan view illustrating a method of fabricating an image sensor according to an embodiment, and FIGS. 34A to 34C are sectional views respectively taken along lines A-A′, B-B′, and C-C′ of FIG. 33. FIGS. 35A to 35C are sectional views, which are respectively taken along lines A-A′, B-B′, and C-C′ of FIG. 31 to illustrate a method of fabricating an image sensor according to an embodiment. For the sake of brevity, repeated description of features which are the same as those of FIGS. 5, 6A to 8A, and 6B to 8B will be omitted for conciseness and features, which are different from the method of FIGS. 5, 6A to 8A, and 6B to 8B, will be mainly described below.

Referring to FIGS. 33 and 34A to 34C, first trenches 130Ta may be formed in a substrate 100. The first trenches 130Ta may be extended in the first direction D1 and may be spaced apart from each other in the second direction D2. The formation of the first trenches 130Ta may include forming a first mask pattern (not shown) on the first surface 100a of the substrate 100 to have openings exposing regions, in which the first trenches 130Ta will be formed, and etching the substrate 100 using the first mask pattern as an etch mask. The first mask pattern may be removed, after the formation of the first trenches 130Ta.

A mask layer ML may be formed on the first surface 100a of the substrate 100 to fill the first trenches 130Ta. Thereafter, second trenches 130Tb may be formed in the substrate 100. The second trenches 130Tb may be formed to cross the first trenches 130Ta. s an example, the second trenches 130Tb may be extended in the second direction D2 and may be spaced apart from each other in the first direction D1. The formation of the second trenches 130Tb may include a second mask pattern (not shown) on the mask layer ML to have openings exposing regions, on which the second trenches 130Tb will be formed, and etching the substrate 100 and the mask layer ML using the second mask pattern as an etch mask.

The substrate 100 may include a plurality of pixel regions PXR defined by the first and second trenches 130Ta and 130Tb. The pixel regions PXR may be two-dimensionally arranged in the first direction D1 and the second direction D2.

Referring to FIGS. 31 and 35A to 35C, the mask layer ML may be removed after the formation of the first and second trenches 130Ta and 130Tb. A first impurity region 160 may be formed in each of the pixel regions PXR, and a doped region 152 may be formed in side and bottom surfaces of the substrate 100 exposed by the first and second trenches 130Ta and 130Tb. The doped region 152 may be formed in a portion of the substrate 100, which is adjacent to inner side surfaces and bottom surfaces of the first and second trenches 130Ta and 130Tb. The first impurity regions 160 and the doped region 152 may be formed by substantially the same method as that described with reference to FIGS. 5, 6A, and 6B, and thus repeated description thereof will be omitted for conciseness.

A device isolation layer 130 may be formed to fill the first and second trenches 130Ta and 130Tb, respectively. The device isolation layer 130 may be formed by substantially the same method as that described with reference to FIGS. 2, 7A, and 7B, and thus repeated description thereof will be omitted for conciseness. The device isolation layer 130 may include an isolation pattern 110, which is disposed in the first and second trenches 130Ta and 130Tb, and an insulating pattern 120, which is interposed between the isolation pattern 110 and an inner surface of each of the first and second trenches 130Ta and 130Tb. Subsequent processes may be performed in substantially the same manner as that described with reference to FIGS. 2, 4A, 4B, 8A, and 8B, and thus repeated description thereof will be omitted for conciseness.

According to an embodiment, it may be possible to prevent a leaning issue of the pixel regions PXR and to easily increase an aspect ratio of the pixel regions PXR. Accordingly, it may be possible to reduce a process failure in a process of fabricating the image sensor and to easily improve optical characteristics (e.g., resolution and sensitivity) of the image sensor.

According to various example embodiments described above, it may be possible to prevent a leaning issue of pixel regions and to easily increase an aspect ratio of the pixel regions. Accordingly, it may be possible to reduce a process failure in a process of fabricating the image sensor and to easily improve optical characteristics (e.g., resolution and sensitivity) of the image sensor.

While example embodiments have been particularly shown and described, it will be understood by one of ordinary skill in the art that variations in form and detail may be made therein without departing from the spirit and scope of the attached claims.

1. A image sensor comprising:
a first pixel row and a second pixel row, each of the first and second pixel rows comprising a plurality of pixels arranged in a first direction, the first and second pixel rows being adjacent to each other in a second direction crossing the first direction;
a plurality of device isolation patterns disposed between the first pixel row and the second pixel row, the plurality of device isolation patterns being spaced apart from each other in the first direction; and
a plurality of supporting patterns disposed between the first pixel row and the second pixel row, each of the plurality of supporting patterns interposed between an adjacent two of the plurality of device isolation patterns,
wherein each of the plurality of supporting patterns is connected to corresponding ones of the plurality of pixels.

2. The image sensor of claim 1, wherein each of the plurality of supporting patterns comprises a first doped region extended along a side surface thereof.

3. The image sensor of claim 2, wherein each of the plurality of pixels comprises a second doped region extended along a side surface thereof, and
the first doped region and the second doped region have a same conductivity type.

4. The image sensor of claim 3, wherein each of the plurality of pixels comprises a photoelectric conversion region, and
the second doped region is disposed between the photoelectric conversion region and a corresponding one of the plurality of device isolation patterns.

5. The image sensor of claim 3, wherein the first doped region and the second doped region comprise same impurities.

6. The image sensor of claim 1, wherein each of the plurality of device isolation patterns comprises:
an isolation pattern disposed between an adjacent two of the plurality of supporting patterns; and
an insulating pattern interposed between the isolation pattern and each of the adjacent two of the plurality of supporting patterns.

7. The image sensor of claim 6, wherein the isolation pattern is disposed between corresponding ones of the plurality of pixels, and
the insulating pattern is extended into a region between the isolation pattern and each of the corresponding ones of the plurality of pixels.

8. The image sensor of claim 6, wherein the isolation pattern comprises a semiconductor material or a metallic material.

9. The image sensor of claim 6, wherein each of the plurality of supporting patterns comprises a first doped region extended along a side surface thereof, and
the insulating pattern is disposed between the isolation pattern and the first doped region of each of the adjacent two of the plurality of supporting patterns.

10. The image sensor of claim 9, wherein each of the plurality of pixels comprises a second doped region extended along a side surface thereof,
the isolation pattern is disposed between corresponding ones of the plurality of pixels, and
the insulating pattern is extended into a region between the isolation pattern and the second doped region of each of the corresponding ones of the plurality of pixels.

11. A image sensor comprising:
a first pixel row and a second pixel row, each of the first and second pixel rows comprising a plurality of pixels arranged in a first direction, the first and second pixel rows being adjacent to each other in a second direction crossing the first direction;
a plurality of first device isolation patterns disposed between the first pixel row and the second pixel row, the plurality of first device isolation patterns being spaced apart from each other in the first direction; and
a plurality of second device isolation patterns disposed between the plurality of first device isolation patterns,
wherein each of the plurality of second device isolation patterns comprises:
an isolation pattern disposed between corresponding ones of the plurality of first device isolation patterns; and
an insulating pattern interposed between the isolation pattern and each of the corresponding ones of the plurality of first device isolation patterns.

12. The image sensor of claim 11, wherein each of the plurality of first device isolation patterns comprises:
a first isolation pattern disposed between corresponding ones of the plurality of pixels; and
a first insulating pattern interposed between each of the corresponding ones of the plurality of pixels and the first isolation pattern,
wherein the isolation pattern and the insulating pattern of each of the plurality of second device isolation patterns are a second isolation pattern and a second insulating pattern, respectively, and
the second insulating pattern is disposed between the first isolation pattern and the second isolation pattern.

13. The image sensor of claim 12, wherein the first isolation pattern and the second isolation pattern comprise a semiconductor material or a metallic material.

14. The image sensor of claim 12, wherein the second isolation pattern is extended in the second direction and into regions between adjacent ones of the plurality of pixels in the first pixel row and between adjacent ones of the plurality of pixels in the second pixel row, and
the second insulating pattern is extended in the second direction and into regions between the second isolation pattern and each of the adjacent ones of the plurality of pixels.

15. The image sensor of claim 14, wherein each of the plurality of pixels comprises:
a photoelectric conversion region; and
a doped region disposed between the photoelectric conversion region and a corresponding one of the plurality of first device isolation patterns,
wherein the first insulating pattern is disposed between the doped region and the first isolation pattern.

16. The image sensor of claim 15, wherein the doped region is extended into a region between the photoelectric conversion region and a corresponding one of the plurality of second device isolation patterns, and
the second insulating pattern is disposed between the doped region and the second isolation pattern.

17. The image sensor of claim 15, wherein the first isolation pattern comprises an additional doped region adjacent to the second insulating pattern, and
each of the doped region and the additional doped region comprise impurities of a same conductivity type.

18. The image sensor of claim 12, wherein the first isolation pattern comprises a doped region adjacent to the second insulating pattern, and
the second insulating pattern is disposed between the doped region and the second isolation pattern.

19. The image sensor of claim 12, wherein the first insulating pattern is extended into a region between the first isolation pattern and the second insulating pattern.

20. The image sensor of claim 11, wherein each of the plurality of second device isolation patterns is extended in the second direction to cross the first pixel row and the second pixel row.

21-25. (canceled)
